(19) United States
(12) Patent Application Publication
(10) Pub. No.: US 2026/0216749 A1
(43) Pub. Date: Jul. 30, 2026

(54) MULTILAYER STRUCTURE, METHOD FOR PRODUCING THE SAME, AND PROTECTIVE SHEET FOR ELECTRONIC DEVICE AND ELECTRONIC DEVICE USING THE SAME

(71) Applicant: Kuraray Co., Ltd., Okayama (JP)

(72) Inventors: Shuhei KUZUME, Kurashiki-shi, Okayama (JP); Yuho KAWABE, Kurashiki-shi, Okayama (JP)

(73) Assignee: Kuraray Co., Ltd., Okayama (JP)

(21) Appl. No.: 19/139,946

(22) PCT Filed: Dec. 21, 2023
(86) PCT No.: PCT/JP2023/046046

§ 371 Date: Jun. 17, 2025

(30) Foreign Application Priority Data
Dec. 22, 2022 (JP) 2022-205455
Dec. 22, 2022 (JP) 2022-205456
Dec. 22, 2022 (JP) 2022-205457

(51) Int. Cl. B05D 3/02; H05K 5/03

(52) U.S. Cl. CPC B05D 3/0254; H05K 5/03; B05D 2401/21

(57) ABSTRACT

The present disclosure provides a multilayer structure comprising a base and a layer, and a method of manufacturing the same.

### TECHNICAL FIELD

The present invention relates to a multilayer structure having high gas barrier properties, high water vapor barrier properties, and high clarity, a method for producing the same, and a protective sheet for an electronic device and an electronic device using the same.

### DISCUSSION OF THE BACKGROUND

An electronic device such as electronic equipment or the like including a solar cell and/or a display device requires a light-transmitting protective member for protecting a surface. As such a protective member, for example, a thick glass plate, a protective sheet which includes a barrier layer on a resin base and has superior barrier properties (oxygen barrier properties and water vapor barrier properties), or the like may be used.

For example, Patent Document 1 discloses an electronic device which includes, as the protective sheet having superior barrier properties, a protective sheet including a multilayer structure obtained in such a manner that a coating liquid containing an aluminum-containing compound and a phosphorus compound is applied onto a base (X) and then drying and a heat treatment are performed to provide a layer (Y) containing a reaction product, wherein the reaction product has an average particle diameter of 5 to 70 nm. Patent Document 1 discloses that the protective sheet is superior in gas barrier properties and water vapor barrier properties and can maintain its performance even after a dump heat test.

### PRIOR ART DOCUMENT

### Patent Document

Patent Document 1: PCT International Patent Application, Publication No. 2016/103720

### SUMMARY OF THE INVENTION

### Problems to be Solved by the Invention

Recently, a protective sheet (multilayer structure) for an electronic device or the like has been sometimes required to have a higher level of clarity, and sufficient clarity may not be obtained in the multilayer structure used in the conventional electronic device. The high barrier properties of the multilayer structure used in the conventional electronic device are advantageous for a protective sheet for an electronic device or the like, and there is a demand for a multilayer structure having high clarity while maintaining such performance.

The present invention has been made in view of the foregoing circumstances, and an object thereof is to provide a multilayer structure having high barrier properties and clarity, a method for producing the same, and a protective sheet for an electronic device and an electronic device using the same.

### Means for Solving the Problems

The present inventors have repeatedly attempted to realize a multilayer structure having high clarity by using a base having high image clarity as the base (X); however, it has been difficult to achieve high clarity. As a result of intensive studies, the present inventors have found that the a* value and the b* value of the L*a*b* color system are related to the clarity of the multilayer structure. Furthermore, they have found that the a* value and the b* value are related to the time period from the completion of the coating with the coating liquid to drying start time in the formation of the layer (Y) and have completed the present invention.

That is to say, the present invention can be achieved by providing any of the following:
(1) a multilayer structure including a base (X) and a layer (Y), wherein the layer (Y) contains a reaction product (D) between an aluminum atom-containing metal oxide (A) and an inorganic phosphorus compound (BI), the base (X) and the layer (Y) are adjacent to each other in at least one pair of the same, and in a L*a*b* color system, an a* value is −0.8 or more and 0.8 or less and a b* value is −0.8 or more and 0.8 or less, the a* value and the b* value being measured in accordance with JIS Z 8722:2009;
(2) the multilayer structure according to (1), wherein the following condition 1 is satisfied:

### Condition 1:

in a luminance analysis in which reflected light observed when the multilayer structure is moved at a constant speed in a machine direction (MD) in a state in which the multilayer structure is irradiated with light from a white light source is intermittently measured with a line sensor camera; the light from the white light source is delivered to one face of the multilayer structure at an angle of 250 with respect to a vertical direction of the multilayer structure, and the reflected light is measured with the line sensor camera on a face side on which the white light source is provided and at an angle of −30° with respect to the vertical direction of the multilayer structure; and a minimum value of standard deviation of luminance values calculated from values obtained in such a manner that baseline correction is performed on obtained luminance by fitting, by a least-squares method, luminance values within a range of a width (in a transverse direction (TD)) of 12 mm at a center point in the MD of a measurement range is 1.2 or less;
(3) the multilayer structure according to (1) or (2), wherein a surface roughness of the layer (Y) measured by white-light interferometry is 70 nm or less;
(4) the multilayer structure according to any one of (1) to (3), wherein a water vapor transmission rate is 1×10⁻²·g/m²·day or less as measured at 40° C. and 90% RH in accordance with ISO 15106-3:2003;
(5) the multilayer structure according to any one of (1) to (4), wherein the base (X) includes a surface layer;
(6) the multilayer structure according to any one of (1) to (5), including at least one pair of the base (X) and the layer (Y) which are directly laminated;
(7) the multilayer structure according to any one of (1) to (6), including at least one pair of the base (X) and the layer (Y) which are laminated via an adhesive layer (I);
(8) the multilayer structure according to any one of (1) to (7), including layers (Y) respectively disposed on both faces of the base (X);
(9) the multilayer structure according to any one of (1) to (8), wherein in an infrared absorption spectrum of the layer (Y), a maximum absorption wavenumber in a region of 800 to 1,400 cm⁻¹ falls within a range of 1,080 to 1,130 cm⁻¹;
(10) the multilayer structure according to any one of (1) to (9), wherein an image clarity of the base (X) at an optical comb width of 0.25 mm, the image clarity being measured in accordance with ISO 17221, is 85% or more;
(11) the multilayer structure according to any one of (1) to (10), wherein a difference between the a* value and the b* value (a* value−b* value) is −1.0 or more and 1.0 or less;
(12) a method for producing a multilayer structure, the method including: a step (I) of forming a precursor layer of a layer (Y) by applying, onto at least one face of a base (X), a coating liquid (S) containing an aluminum atom-containing metal oxide (A), an inorganic phosphorus compound (BI), and a solvent, followed by drying the coating liquid (S) by heating at a temperature of 120° C. or more to remove the solvent; and a step (II) of forming the layer (Y) by subjecting the precursor layer of the layer (Y) to a heat treatment, wherein in the step (I), a time period from the completion of the coating with the coating liquid (S) to the start of the drying by heating is 1.8 sec or more and 9.0 sec or less, and in a L*a*b* color system of the multilayer structure obtained, an a* value is −0.8 or more and 0.8 or less and a b* value is −0.8 or more and 0.8 or less, the a* value and the b* value being measured in accordance with JIS Z 8722:2009;
(13) the method for producing a multilayer structure according to (12), wherein the coating liquid (S) satisfies the following condition 2:
   condition 2:
   two seconds after a droplet of 2.0 μL of the coating liquid (S) is dropped at 23° C. and 50% RH onto a treatment face of a polyethylene terephthalate film which has been subjected to a surface treatment at an intensity of 130 W min/m² by using a corona treatment device, a contact angle of the droplet is 200 or more and 350 or less;
(14) the method for producing a multilayer structure according to (13), wherein the coating liquid (S) contains a water/methanol mixed solvent as the solvent, and the mixed solvent has a water/methanol ratio of 3.5/6.5 or more and 7/3 or less;
(15) the method for producing a multilayer structure according to any one of (12) to (14), wherein the coating liquid (S) has a viscosity of 400 mPa·s or more and 5,000 mPa·s or less, and a surface roughness of the layer (Y) measured by white-light interferometry is 70 nm or less;
(16) a protective sheet for an electronic device, the protective sheet including the multilayer structure according to any one of (1) to (11);
(17) the protective sheet according to (16), which is to be used in protecting a surface of a photoelectric conversion device, an information display device, or a lighting device; and
(18) an electronic device including the protective sheet according to (16) or (17).

### Effects of the Invention

According to the present invention, a multilayer structure having high barrier properties and clarity, a method for producing the same, and a protective sheet for an electronic device and an electronic device using the same can be provided.

### DESCRIPTION OF EMBODIMENTS

As referred to herein, the “barrier properties” principally mean both oxygen barrier properties and water vapor barrier properties, and the “gas barrier properties” principally mean oxygen barrier properties. Furthermore, the “clarity” is used to evaluate the clarity of an image seen through the multilayer structure of the present invention and is determined by the visibility at the time of visually observing an image seen through the multilayer structure of the present invention, as disclosed in EXAMPLES.

The multilayer structure of the present invention is a multilayer structure including a base (X) and a layer (Y), wherein the layer (Y) contains a reaction product (D) between a metal oxide (A) and an inorganic phosphorus compound (BI), the base (X) and the layer (Y) are adjacent to each other in at least one pair of the same, and in a L*a*b* color system, an a* value is −0.8 or more and 0.8 or less and a b* value is −0.8 or more and 0.8 or less, the a* value and the b* value being measured in accordance with JIS Z 8722:2009. As referred to herein, the term “adjacent” means that layers are directly laminated or laminated via another layer such as an adhesive layer or the like. Furthermore, the expression “the base (X) and the layer (Y) are adjacent to each other in at least one pair of the same” means that, for example, in a case in which a plurality of bases (X) are provided, it is only necessary that one of the bases (X) is adjacent to the layer (Y), and the other bases (X) do not need to be adjacent to the layer (Y). Similarly, in a case in which a plurality of layers (Y) are provided, it is only necessary that one of the layers (Y) is adjacent to the base (X), and the other layers (Y) do not need to be adjacent to the base (X). All the bases (X) are preferably adjacent to the respective layers (Y). Furthermore, all the layers (Y) are preferably adjacent to the respective bases (X). When in the L*a*b* color system of the multilayer structure of the present invention, the a* value is −0.8 or more and 0.8 or less and the b* value is −0.8 or more and 0.8 or less, the a* value and the b* value being measured in accordance with JIS Z 8722:2009, for example, the multilayer structure in a case of being used as a protective sheet for an electronic device is superior in clarity. Although details of a procedure for setting the a* value and the b* of the multilayer structure of the present invention within the above range will be described later, it is particularly important that the base (X) has high image clarity and that the time period from the completion of coating with a coating liquid (S) to the start of drying by heating falls within a range of 1.8 sec or more and 9.0 sec or less.

### Base (X)

The base (X) is not particularly limited and preferably contains a thermoplastic resin in light of its high image clarity. The mode of the base (X) is not particularly limited and is preferably a layered shape such a film, a sheet, or the like. The base (X) preferably includes a thermoplastic resin film or a thermoplastic resin film on which an inorganic vapor-deposited layer (X′) is laminated, more preferably includes a thermoplastic resin film, and is still more preferably a thermoplastic resin film.

Examples of the thermoplastic resin used in the base (X) include: polyolefin resins such as polyethylene and polypropylene; polyester resins such as polyethylene terephthalate (PET), polyethylene-2,6-naphthalate, polybutylene terephthalate, and copolymers thereof; polyamide resins such as nylon-6, nylon-66, and nylon-12; hydroxyl group-containing polymers such as polyvinyl alcohol and an ethylene-vinyl alcohol copolymer; polystyrene; poly(meth)acrylic acid ester; polyacrylonitrile; polyvinyl acetate; polycarbonate; polyarylate; regenerated cellulose; polyimide; polyetherimide; polysulfone; polyethersulfone; polyetheretherketone; ionomer resins; and the like. The thermoplastic resin used in the base (X) is preferably at least one selected from the group consisting of polyethylene, polypropylene, polyethylene terephthalate, nylon-6, and nylon-66, and more preferably polyethylene terephthalate in light of its superior image clarity.

The base (X) may contain inorganic microparticles or organic microparticles to impart slipperiness and/or blocking resistance; in the case of containing the inorganic microparticles or the organic microparticles, in light of the image clarity of the base (X), the base (X) preferably contains them in a surface layer described later. That is to say, in light of the image clarity, it may be preferable that the inorganic microparticles or the organic microparticles are not contained except in the surface layer of the base (X). As the inorganic microparticles, for example, a metal such as gold, silver, copper, platinum, palladium, rhenium, vanadium, osmium, cobalt, iron, zinc, ruthenium, praseodymium, chromium, nickel, aluminum, tin, zinc, titanium, tantalum, zirconium, antimony, indium, yttrium, or lanthanum; a metal oxide such as zinc oxide, titanium oxide, cesium oxide, antimony oxide, tin oxide, indium-tin oxide, yttrium oxide, lanthanum oxide, zirconium oxide, aluminum oxide, or silicon oxide; a metal fluoride such as lithium fluoride, magnesium fluoride, aluminum fluoride, or cryolite; a metal phosphate such as calcium phosphate; a carbonate such as calcium carbonate; a sulfate such as barium sulfate; talc; kaolin; or the like may be used. As the organic microparticles, a silicone compound or cross-linked microparticles such as cross-linked styrene, cross-linked acrylic, or cross-linked melamine may be used, or a thermoplastic resin which is incompatible with the thermoplastic resin constituting the base layer (X) but forms a sea-island structure by being finely dispersed therein may also be used as the microparticles. The microparticles to be used preferably have an average particle diameter of 0.001 to 5 μm.

In the case in which the thermoplastic resin film is used as the base (X), the base (X) may be a stretched film or an unstretched film. In light of the fact that the multilayer structure to be obtained can have superior processing suitability (printing, lamination, etc.), a stretched film, particularly a biaxially stretched film is preferred. The biaxially stretched film may be a biaxially stretched film produced by any of a simultaneous biaxial stretching method, a sequential biaxial stretching method, and a tubular stretching method.

A thickness per layer of the base (X) is preferably 5 μm or more and 200 μm or less, more preferably 7 μm or more and 150 μm or less, and still more preferably 10 μm or more and 100 μm or less. When the thickness per layer of the base (X) is 5 μm or more, the base (X) tends to have superior mechanical strength and processability. Furthermore, when the thickness per layer of the base (X) is 200 μm or less, the multilayer structure to be obtained tends to have superior flexibility.

The base (X) preferably has high image clarity, and the image clarity of the base (X) is preferably 85% or more, more preferably 90% or more, and still more preferably 92% or more. In light of the production cost, the image clarity of the base (X) may be 99% or less, 97% or less, 96% or less, or 95% or less. When the image clarity of the base (X) is 85% or more, the a* value and the b* value of the multilayer structure to be obtained can be easily adjusted to −0.8 or more and 0.8 or less. Furthermore, when the image clarity of the base (X) is 85% or more, standard deviation of luminance values of the multilayer structure described later can be easily controlled to be small, and a surface roughness of the layer (Y) can also be easily adjusted to a small value. The image clarity of the base (X) is defined as an average value of five measured values measured at an optical comb width of 0.25 mm in accordance with ISO 17221.

Examples of a means for adjusting the image clarity of the base (X) to 85% or more include: containing no additive (e.g., inorganic microparticles or organic microparticles) or only a few additives, if any, in a layer other than the surface layer described later; providing the surface layer described later; and the like.

In light of imparting a variety of functions and improving the image clarity of the base (X), the base (X) preferably includes the surface layer. The surface layer is a layer provided on a surface of the base (X) and may be provided on one face or both faces of the base (X). The surface layer is not particularly limited as long as it has adhesiveness with respect to the material used in the base (X) and preferably contains a thermoplastic resin as a principle component. As referred to herein, the “principle component” means a component having a content of greater than 50% by mass. As the thermoplastic resin, a polyester resin, a polycarbonate resin, an epoxy resin, an alkyd resin, an acrylic resin, a urea resin, a urethane resin, or the like can be suitably used. Furthermore, two or more different types of thermoplastic resins, for example, a polyester resin and a urethane resin, a polyester resin and an acrylic resin, a urethane resin and an acrylic resin, etc. may be used in combination. Of these, at least one selected from the group consisting of a polyester resin, an acrylic resin, and a urethane resin is preferred, and a polyester resin is more preferred.

In light of improving the heat-resistant adhesiveness as well as dramatically improving the moisture-resistant adhesiveness, it may be preferable that the surface layer contains a variety of cross-linking agents. Particularly in a case in which a polyester resin, a urethane resin, or an acrylic resin is used as the principle component of the surface layer and copolymerized with a cross-linkable functional group, a cross-linking agent is preferably further contained. The thermoplastic resin and the cross-linking agent which constitute the surface layer may be mixed and used in an arbitrary ratio; in terms of improving the adhesiveness, the content of the cross-linking agent is preferably 0.2 to 20 parts by mass, more preferably 0.5 to 15 parts by mass, and still more preferably 1 to 10 parts by mass with respect to 100 parts by mass of the resin.

The surface layer may contain the above-described inorganic microparticles or organic microparticles to impart slipperiness and/or blocking resistance.

A commercial product may be used as the base (X), and examples of a commercial product having high image clarity include: Lumirror (registered trademark) U403, U483, A48, and XW731C, produced by Toray Industries, Inc.; RH210, produced by HYOSUNG Corporation; DIAFOIL (registered trademark) T600, produced by Mitsubishi Chemical Group Corporation; COSMOSHINE (registered trademark) A4160 and SRF, and a Toyobo Ester (registered trademark) film HPE, produced by TOYOBO Co., Ltd.; and the like. These products include the surface layer on one face or both faces.

In light of the coating properties of the coating liquid (S) described later and the barrier properties of the multilayer structure to be obtained, the base (X) is preferably subjected to a surface treatment. The surface treatment may be performed by a known method, and examples thereof include a UV ozone treatment, a high-concentration ozone water treatment, an excimer ozone treatment, a corona treatment, an oxygen plasma treatment, an AP plasma treatment, and the like.

The thermoplastic resin film which includes the inorganic vapor-deposited layer (X′) laminated thereon and is used as the base (X) is typically a transparent film having barrier properties against oxygen and water vapor. In the case in which the thermoplastic resin film including the inorganic vapor-deposited layer (X′) laminated thereon is used as the base (X), the layer (Y) described later is typically laminated on the inorganic vapor-deposited layer (X′) side. As a thermoplastic resin film used as the thermoplastic resin film including the inorganic vapor-deposited layer (X′) laminated thereon, the thermoplastic resin film described above as an example of the base (X) may be used. The inorganic vapor-deposited layer (X′) can be formed by vapor-depositing an inorganic substance. Examples of the inorganic substance include metal oxides (e.g., silicon oxide and aluminum oxide), metal nitrides (e.g., silicon nitride), metal nitride oxides (e.g., silicon oxynitride), and the like. Of these, the inorganic vapor-deposited layer (X′) formed of aluminum oxide, silicon oxide, magnesium oxide, or silicon nitride is preferred in light of its superior transparency. It is to be noted that in light of the image clarity, it may be preferable that the inorganic vapor-deposited layer (X′) is not included.

A method for forming the inorganic vapor-deposited layer (X′) is not particularly limited, and examples thereof include: physical vapor deposition methods such as a vacuum deposition method (e.g., resistance heating deposition, electron beam deposition, a molecular beam epitaxy method, etc.), a sputtering method, and an ion plating method; and chemical vapor deposition methods such as a thermal chemical vapor deposition method (e.g., a catalyst chemical vapor deposition method), a photo-chemical vapor deposition method, a plasma chemical vapor deposition method (e.g., capacitively coupled plasma, inductively coupled plasma, surface wave plasma, electron cyclotron resonance, dual magnetron, an atomic layer deposition method, etc.), and a metal-organic chemical vapor deposition method.

A thickness of the inorganic vapor-deposited layer (X′) varies depending on the type of a component constituting the inorganic vapor-deposited layer and is preferably 0.002 to 0.5 μm, more preferably 0.005 to 0.2 μm, and still more preferably 0.01 to 0.1 μm. The thickness may be selected from this range such that the multilayer structure can have favorable barrier properties and mechanical properties. When the thickness of the inorganic vapor-deposited layer (X′) is 0.002 μm or more, the inorganic vapor-deposited layer (X′) tends to have favorable barrier properties against oxygen and water vapor. Furthermore, when the thickness of the inorganic vapor-deposited layer (X′) is 0.5 μm or less, the barrier properties of the inorganic vapor-deposited layer (X′) after bending tend to be sufficiently maintained.

As the base (X), one type of a base may be used alone, or a combination of two or more types of bases may be used. In a case in which a plurality of bases (X) are provided, the bases (X) may be the same or different from each other.

### Layer (Y)

The layer (Y) contains the reaction product (D) between the metal oxide (A) and the inorganic phosphorus compound (BI). In the multilayer structure of the present invention, the layer (Y) serves as a barrier layer; therefore, when the layer (Y) is provided, the multilayer structure of the present invention tends to have favorable barrier properties. Furthermore, for example, by forming the layer (Y) by an appropriate procedure, in the L*a*b* color system, the a* value can be set to −0.8 or more and 0.8 or less and the b* value can be set to −0.8 or more and 0.8 or less, the a* value and the b* value being measured in accordance with JIS Z 8722:2009. Furthermore, for example, by forming the layer (Y) by an appropriate procedure, the multilayer structure can satisfy condition 1 described in detail later.

### Aluminum Atom-Containing Metal Oxide (A)

Metal atoms constituting the metal oxide (A) (may be collectively referred to as “metal atoms (M)”) are at least one type of metal atom selected from the metal atoms belonging to Groups 2 to 14 of the periodic table and include at least an aluminum atom. The metal atoms (M) are preferably an aluminum atom alone but may include an aluminum atom and other metal atom(s). It is to be noted that a mixture of two or more types of metal oxides (A) may be used as the metal oxide (A). Examples of metal atoms other than the aluminum atom include the metals of Group 2 of the periodic table, such as magnesium and calcium; the metals of Group 12 of the periodic table, such as zinc; the metals of Group 13 of the periodic table; the metals of Group 14 of the periodic table, such as silicon; transition metals such as titanium and zirconium; and the like. It is to be noted that silicon may be categorized as a semimetal; however, silicon as referred to herein is included in the category of metal. In light of the handleability and the fact that the multilayer structure to be obtained can have superior gas barrier properties, the metal atoms (M) which may be used in combination with aluminum are preferably at least one selected from the group consisting of titanium and zirconium.

A proportion of the aluminum atom in the metal atoms (M) is preferably 50 mol % or more, more preferably 70 mol % or more, still more preferably 90 mol % or more, and may be 95 mol % or more, or the metal atoms (M) may substantially consist of only the aluminum atom. Examples of the metal oxide (A) include metal oxides produced by methods such as a solution-phase synthesis method, a vapor-phase synthesis method, a solid grinding method, and the like.

The metal oxide (A) may be a hydrolyzed condensate of a compound (E) containing the metal atoms (M) to which a hydrolyzable characteristic group is bonded (hereinafter, may be abbreviated to “compound (E)”). Examples of the characteristic group include a halogen atom, NO₃, an alkoxy group which has 1 to 9 carbon atoms and may contain a substituent, an aryloxy group which has 6 to 9 carbon atoms and may contain a substituent, an acyloxy group which has 2 to 9 carbon atoms and may contain a substituent, an alkenyloxy group which has 3 to 9 carbon atoms and may contain a substituent, a β-diketonato group which has 5 to 15 carbon atoms and may contain a substituent, a diacylmethyl group having an acyl group which has 1 to 9 carbon atoms and may contain a substituent, and the like. The hydrolyzed condensate of the compound (E) can be substantially regarded as the metal oxide (A). Therefore, the hydrolyzed condensate of the compound (E) as referred to herein may be referred to as “metal oxide (A).” That is to say, as referred to herein, the “metal oxide (A)” can be synonymized with the “hydrolyzed condensate of the compound (E),” and furthermore, the “hydrolyzed condensate of the compound (E)” can be synonymized with the “metal oxide (A).”

Compound (E) Containing Metal Atoms (M) to which Hydrolyzable Characteristic Group is Bonded

The compound (E) preferably contains an aluminum atom-containing compound (Ea) described later, because the reaction with the inorganic phosphorus compound (BI) can be easily controlled and the multilayer structure to be obtained can have superior gas barrier properties.

Examples of the compound (Ea) include aluminum chloride, aluminum nitrate, aluminum acetate, tris(2,4-pentandionato) aluminum, trimethoxyaluminum, triethoxyaluminum, tri-n-propoxyaluminum, triisopropoxyaluminum, tri-n-butoxyaluminum, tri-sec-butoxyaluminum, tri-tert-butoxyaluminum, and the like; of these, triisopropoxyaluminum and tri-sec-butoxyaluminum are preferred. Two or more types of compounds (Ea) may be used in combination.

Furthermore, the compound (E) may contain a compound (Eb) containing the metal atoms (M) other than aluminum, and examples of the compound (Eb) include: titanium compounds such as tetrakis(2,4-pentandionato) titanium, tetramethoxytitanium, tetraethoxytitanium, tetraisopropoxytitanium, tetra-n-butoxytitanium, and tetrakis(2-ethylhexoxy) titanium; zirconium compounds such as tetrakis(2,4-pentandionato) zirconium, tetra-n-propoxyzirconium, and tetra-n-butoxyzirconium; and the like. One type of these compounds may be used alone, or two or more types of compounds (Eb) may be used in combination.

A proportion of the compound (Ea) in the compound (E) is not particularly limited and is, for example, preferably 80 mol % or more, more preferably 90 mol % or more, still more preferably 95 mol % or more, and may be 100 mol %.

When the compound (E) is hydrolyzed, at least part of the hydrolyzable characteristic group contained in the compound (E) is converted to a hydroxyl group. Moreover, when a hydrolyzed product thereof is condensed, a compound in which the metal atoms (M) are bonded through an oxygen atom (O) is formed. When this condensation is repeated, a compound which can be substantially regarded as a metal oxide is formed. It is to be noted that typically, a hydroxyl group exists on a surface of the metal oxide (A) thus formed.

The metal oxide (A) as referred to herein includes a compound in which a ratio [mole number of oxygen atom (O) bonded only to metal atom (M)]/[mole number of metal atom (M)] is 0.8 or more. In this case, the oxygen atom (O) bonded only to the metal atom (M) refers to an oxygen atom (O) in a structure represented by M-O-M, and an oxygen atom bonded to the metal atom (M) and a hydrogen atom (H), such as an oxygen atom (O) in a structure represented by M-O—H, is excluded. The above ratio in the metal oxide (A) is preferably 0.9 or more, more preferably 1.0 or more, and still more preferably 1.1 or more. The upper limit of this ratio is not particularly limited and is typically represented by n/2, wherein n denotes the valence of the metal atom (M).

To allow the hydrolytic condensation, it is important that the compound (E) contains the hydrolyzable characteristic group. In a case in which such a group is not bonded, the hydrolytic condensation reaction does not occur or proceeds extremely slowly, making it difficult to prepare the target metal oxide (A).

The hydrolyzed condensate of the compound (E) may be produced, for example, from a specific raw material by a procedure employed in a known sol-gel method. As the raw material, at least one selected from the group consisting of the compound (E), a partially hydrolyzed product of the compound (E), a completely hydrolyzed product of the compound (E), a compound obtained by partially hydrolytically condensing the compound (E), and a compound obtained by condensing a part of a completely hydrolyzed product of the compound (E) may be used.

It is to be noted that the metal oxide (A) to be mixed with an inorganic phosphorus compound (BI)-containing material (the inorganic phosphorus compound (BI) or a composition containing the inorganic phosphorus compound (BI)) described later preferably contains substantially no phosphorus atom.

### Inorganic Phosphorus Compound (BI)

The inorganic phosphorus compound (BI) has a site which can react with the metal oxide (A), typically has a plurality of such sites, and preferably has 2 to 20 sites. Such sites include a site capable of a condensation reaction with a functional group (e.g., hydroxyl group) existing on the surface of the metal oxide (A) and are exemplified by a halogen atom directly bonded to a phosphorus atom, an oxygen atom directly bonded to a phosphorus atom, and the like. The functional group (e.g., hydroxyl group) existing on the surface of the metal oxide (A) is typically bonded to the metal atom (M) constituting the metal oxide (A).

Examples of the inorganic phosphorus compound (BI) include: oxo aids of phosphorus, such as phosphoric acid, diphosphoric acid, triphosphoric acid, polyphosphoric acid in which four or more phosphoric acid molecules are condensed, phosphorous acid, phosphonic acid, phosphonous acid, phosphinic acid, and phosphinous acid; salts thereof (e.g., sodium phosphate); derivatives thereof (e.g., halides (e.g., phosphoryl chloride); dehydration products thereof (e.g., diphosphorus pentaoxide)); and the like, and one type may be used alone, or two or more types may be used in combination. Of these, in light of the fact that the stability of the coating liquid (S) described later and the gas barrier properties of the multilayer structure to be obtained can be improved, it is preferable to use phosphorus acid alone or to use phosphorus acid and an other inorganic phosphorus compound (BI) in combination. In the case in which phosphorus acid and the other inorganic phosphorus compound (BI) are used in combination, the phosphorus acid preferably accounts for 50 mol % or more of the inorganic phosphorus compound (BI).

### Reaction Product (D)

The reaction product (D) is obtained by a reaction between the metal oxide (A) and the inorganic phosphorus compound (BI). The reaction product (D) also includes a compound generated by a reaction among the metal oxide (A), the inorganic phosphorus compound (BI), and another compound.

In an infrared absorption spectrum of the layer (Y), a maximum absorption wavenumber in a region of 800 to 1,400 cm⁻¹ preferably falls within a range of 1,080 to 1,130 cm⁻¹. For example, in the process in which the metal oxide (A) and the inorganic phosphorus compound (BI) are reacted to produce the reaction product (D), the metal atom (M) derived from the metal oxide (A) and a phosphorus atom (P) derived from the inorganic phosphorus compound (BI) form a bond represented by M-O—P through an oxygen atom (O). As a result, a characteristic absorption band derived from this bond occurs in an infrared absorption spectrum of the reaction product (D). In a case in which the characteristic absorption band based on the M-O—P bond is observed in the region of 1,080 to 1,130 cm⁻¹, the obtained multilayer structure exhibits superior gas barrier properties. In particular, in a case in which the characteristic absorption band is the strongest absorption in the region of 800 to 1,400 cm 1, in which absorptions derived from bonds between a variety of atoms and oxygen atoms are typically observed, the obtained multilayer structure exhibits further superior gas barrier properties.

In contrast, in a case in which a metal compound such as the compound (E) or a metal salt and the inorganic phosphorus compound (BI) are premixed and then subjected to hydrolytic condensation, a complex in which a metal atom derived from the metal compound and the phosphorus atom derived from the inorganic phosphorus compound (BI) are substantially uniformly mixed and reacted is obtained. In this case, in the infrared absorption spectrum, the maximum absorption wavenumber in the region of 800 to 1,400 cm⁻¹ is out of the range of 1,080 to 1,130 cm⁻¹.

In the infrared absorption spectrum of the layer (Y), a half-value width of the maximum absorption band in the region of 800 to 1,400 cm⁻¹ is preferably 200 cm⁻¹ or less, more preferably 150 cm⁻¹ or less, still more preferably 100 cm⁻¹ or less, and particularly preferably 50 cm⁻¹ or less in light of the gas barrier properties of the multilayer structure to be obtained.

The infrared absorption spectrum of the layer (Y) can be measured in a measurement region of 800 to 1,400 cm⁻¹ by an attenuated total reflection method by using a Fourier transform infrared spectrophotometer (Spectrum One, produced by PerkinElmer, Inc.). It is to be noted that in a case in which the measurement by the above method is impossible, the infrared absorption spectrum may be measured, but not limited to, by reflection measurement such as a reflection absorption method, an external reflection method, or an attenuated total reflection method or by a method in which the layer (Y) is scraped from the multilayer structure and subjected to transmission measurement such as a Nujol method or a tablet method.

Furthermore, the layer (Y) may partly contain the metal oxide (A) and/or the inorganic phosphorus compound (BI) which are/is not involved in the reaction.

In the layer (Y), a molar ratio of the metal atom constituting the metal oxide (A) to the phosphorus atom derived from the inorganic phosphorus compound (BI) preferably falls within a range of [metal atom constituting metal oxide (A)]:[phosphorus atom derived from inorganic phosphorus compound (BI)]=1.0:1.0 to 3.6:1.0 and more preferably within a range of 1.1:1.0 to 3.0:1.0. Within this range, superior gas barrier performance can be obtained. The molar ratio in the layer (Y) can be adjusted by a mixture ratio between the metal oxide (A) and the inorganic phosphorus compound (BI) in the coating liquid (S) for forming the layer (Y). The molar ratio in the layer (Y) is typically equal to the ratio in the coating liquid (S).

Besides the above-described components, the layer (Y) may further contain other component(s). Examples of the other component(s) which may be contained in the layer (Y) include: a polymer (F) having at least one functional group selected from the group consisting of a carbonyl group, a hydroxyl group, a carboxyl group, a carboxylic anhydride group, and a salt of a carboxyl group (hereinafter, may be abbreviated to “polymer (F)”); an organic phosphorus compound (BO); a cross-linking agent-containing resin composition (V); inorganic acid metal salts such as carbonate, hydrochloride, nitrate, hydrogen carbonate, sulfate, hydrogen sulfate, and borate; organic acid metal salts such as oxalate, acetate, tartrate, and stearate; metal complexes such as a cyclopentadienyl metal complex (e.g., titanocene) and a cyano metal complex (e.g., Prussian blue); a layered clay compound; a cross-linking agent; a high-molecular compound other than the polymer (F); a plasticizer; an antioxidant; an ultraviolet absorbing agent, a flame retardant; and the like. A content percentage of the other component(s) in the layer (Y) of the multilayer structure is preferably 50% by mass or less, more preferably 20% by mass or less, still more preferably 10% by mass or less, particularly preferably 5% by mass or less, and may be 4% by mass or less, 3% by mass or less, 2% by mass or less, 1% by mass or less, or 0% by mass (no other component(s) may be contained). In light of the fact that the multilayer structure of the present invention can have higher clarity, the content of the other component(s) is preferably low.

### Polymer (F)

The polymer (F) has at least one functional group selected from the group consisting of a carbonyl group, a hydroxyl group, a carboxyl group, a carboxylic anhydride group, and a salt of a carboxyl group. The polymer (F) is preferably a polymer having at least one functional group selected from the group consisting of a hydroxyl group and a carboxyl group.

Examples of the polymer (F) include: polyethylene glycol; polyvinyl alcohol polymers such as a polyvinyl alcohol, a modified polyvinyl alcohol containing 1 to 50 mol % of an α-olefin unit having 4 or less carbon atoms, and polyvinyl acetal (e.g., polyvinyl butyral); polysaccharides such as cellulose and starch; (meth)acrylic acid polymers such as polyhydroxyethyl (meth)acrylate, poly(meth)acrylic acid, and an ethylene-acrylic acid copolymer; maleic acid polymers such as a hydrolyzed product of an ethylene-maleic anhydride copolymer, a hydrolyzed product of a styrene-maleic anhydride copolymer, and a hydrolyzed product of an isobutylene-maleic anhydride alternating copolymer; and the like. Of these, polyethylene glycol and a polyvinyl alcohol polymer are preferred.

The polymer (F) may be a homopolymer of a monomer having a polymerizable group, may be a copolymer of two or more types of monomers, or may be a copolymer of a monomer having at least one functional group selected from the group consisting of a carbonyl group, a hydroxyl group, a carboxyl group, a carboxylic anhydride group, and a salt of a carboxyl group and a monomer which does not have the group. It is to be noted that a mixture of two or more types of polymers (F) may be used as the polymer (F).

A molecular weight of the polymer (F) is not particularly limited; to obtain a multilayer structure having further superior gas barrier properties and mechanical strength, a weight-average molecular weight of the polymer (F) is preferably 5,000 or more, more preferably 8,000 or more, and still more preferably 10,000 or more. The upper limit of the weight-average molecular weight of the polymer (F) is not particularly limited and is, for example, 1,500,000 or less.

In light of keeping favorable appearance of the multilayer structure, a content of the polymer (F) in the layer (Y) is preferably less than 50% by mass, more preferably 20% by mass or less, still more preferably 10% by mass or less, and may be 0% by mass on the basis of the mass of the layer (Y). The polymer (F) may or may not be reacted with a component in the layer (Y).

### Organic Phosphorus Compound (BO)

The organic phosphorus compound (BO) is preferably a polymer (BOa) having a plurality of phosphorus atoms or an organic phosphorus compound (BOb).

Polymer (BOa) Having Plurality of Phosphorus Atoms Examples of a functional group containing the phosphorus atoms of the polymer (BOa) include a phosphoric acid group, a phosphorous acid group, a phosphonic acid group, a phosphonous acid group, a phosphinic acid group, a phosphinous acid group, functional groups derived from these groups (e.g., a salt, a (partial) ester compound, a halide (e.g., a chloride), and a dehydration product), and the like; of these, a phosphoric acid group and a phosphonic acid group are preferred, and a phosphonic acid group is more preferred.

Examples of the polymer (BOa) include polymers of phosphono(meth)acrylic acid ester such as 6-[(2-phosphonoacetyl)oxy]hexyl acrylate, 2-phosphonooxyethyl methacrylate, phosphonomethyl methacrylate, 11-phosphonoundecyl methacrylate, and 1,1-diphosphonoethyl methacrylate; polymers of vinylphosphonic acids such as vinylphosphonic acid, 2-propene-1-phosphonic acid, 4-vinylbenzyl phosphonic acid, and 4-vinylphenyl phosphonic acid; polymers of vinyl phosphinic acids such as vinyl phosphinic acid and 4-vinylbenzyl phosphinic acid; phosphorylated starch; and the like. The polymer (BOa) may be a homopolymer of a monomer having at least one phosphorus atom-containing functional group or a copolymer of two or more types of monomers. Furthermore, as the polymer (BOa), two or more types of polymers each consisting of a single monomer may be used in combination. Of these, a polymer of phosphono(meth)acrylic acid ester and a polymer of a vinylphosphonic acid are preferred, a polymer of a vinylphosphonic acid is more preferred, and a polyvinylphosphonic acid is still more preferred. Furthermore, the polymer (BOa) can also be obtained by homo- or copolymerizing a vinylphosphonic acid derivative such as a vinylphosphonic acid halide or vinylphosphonic acid ester and then hydrolyzing the resulting polymer.

Furthermore, the polymer (BOa) may be a copolymer of the monomer having at least one phosphorus atom-containing functional group and an other vinyl monomer. Examples of the other vinyl monomer which can be copolymerized with the monomer having the phosphorus atom-containing functional group include (meth)acrylic acid, (meth)acrylic acid ester, acrylonitrile, methacrylonitrile, styrene, nuclear-substituted styrene, alkyl vinyl ether, alkyl vinyl ester, perfluoroalkyl vinyl ether, perfluoroalkyl vinyl ester, maleic acid, maleic anhydride, fumaric acid, itaconic acid, maleimide, phenyl maleimide, and the like; of these, (meth)acrylic acid ester, acrylonitrile, styrene, maleimide, and phenyl maleimide are preferred.

To obtain a multilayer structure having superior bending resistance, a proportion of a structural unit derived from the monomer having the phosphorus atom-containing functional group in all structural units of the polymer (BOa) is preferably 10 mol % or more, more preferably 40 mol % or more, still more preferably 70 mol % or more, particularly preferably 90 mol % or more, and may be 100 mol %.

A molecular weight of the polymer (BOa) is not particularly limited, and a number-average molecular weight thereof preferably falls within a range of 1,000 to 100,000. When the number-average molecular weight falls within this range, both an effect of improving the bending resistance of the multilayer structure of the present invention and the viscosity stability of the coating liquid (S) described later in the case of using the coating liquid (S) can be achieved at a high level.

In the case in which the layer (Y) of the multilayer structure contains the polymer (BOa), a ratio WBOa/WBI of a mass WBOa of the polymer (BOa) to a mass WBI of the inorganic phosphorus compound (BI) in the layer (Y) preferably satisfies a relation of 0.01/99.99≤WBOa/WBI<6.00/94.00, in light of superior barrier performance, more preferably satisfies a relation of 0.10/99.90≤WBOa/WBI<4.50/95.50, still more preferably satisfies a relation of 0.20/99.80≤WBOa/WBI<4.00/96.00, and particularly preferably satisfies a relation of 0.50/99.50≤WBOa/WBI<3.50/96.50. That is to say, the WBI is preferably as large as greater than 94.00 and 99.99 or less, whereas the WBOa is as small as 0.01 or more and less than 6.00. It is to be noted that even in a case in which the inorganic phosphorus compound (BI) and/or the organic phosphorus compound (BOa) have/has undergone a reaction in the layer (Y), the part of the inorganic phosphorus compound (BI) and/or the organic phosphorus compound (BOa) which constitutes the reaction product (D) is regarded as the inorganic phosphorus compound (BI) and/or the organic phosphorus compound (BOa). In this case, the mass of the inorganic phosphorus compound (BI) and/or the organic phosphorus compound (BOa) used in the formation of the reaction product (D) (mass of the inorganic phosphorus compound (BI) and/or the organic phosphorus compound (BOa) before the reaction) is included in the mass of the inorganic phosphorus compound (BI) and/or the organic phosphorus compound (BOa) in the layer (Y).

### Organic Phosphorus Compound (BOb)

In the organic phosphorus compound (BOb), a phosphorus atom to which at least one hydroxyl group is bonded is bonded to a polar group through an alkylene chain or a polyoxy alkylene chain having 3 or more and 20 or less carbon atoms. The organic phosphorus compound (BOb) has low surface free energy as compared with the metal oxide (A), the inorganic phosphorus compound (BI), and the reaction product (D) thereof and is segregated on the surface side in the formation process of the precursor of the layer (Y). As a result, the bending resistance of the multilayer structure of the present invention and the adhesiveness between the layer (Y) and a layer directly laminated thereon may be improved.

Examples of the organic phosphorus compound (BOb) include 3-hydroxypropylphosphonic acid, 4-hydroxybutylphosphonic acid, 5-hydroxypentylphosphonic acid, 6-hydroxyhexylphosphonic acid, 7-hydroxyheptylphosphonic acid, 8-hydroxyoctylphosphonic acid, 9-hydroxynonylphosphonic acid, 10-hydroxydecylphosphonic acid, 11-hydroxyundecylphosphonic acid, 12-hydroxydodecylphosphonic acid, 13-hydroxydotridecylphosphonic acid, 14-hydroxytetradecylphosphonic acid, 15-hydroxypentadecylphosphonic acid, 16-hydroxyhexadecylphosphonic acid, 17-hydroxyheptadecylphosphonic acid, 18-hydroxyoctadecylphosphonic acid, 19-hydroxynonadecylphosphonic acid, 20-hydroxyicosylphosphonic acid, 3-hydroxypropyl dihydrogen phosphate, 4-hydroxybutyl dihydrogen phosphate, 5-hydroxypentyl dihydrogen phosphate, 6-hydroxyhexyl dihydrogen phosphate, 7-hydroxyheptyl dihydrogen phosphate, 8-hydroxyoctyl dihydrogen phosphate, 9-hydroxynonyl dihydrogen phosphate, 10-hydroxydecyl dihydrogen phosphate, 11-hydroxyundecyl dihydrogen phosphate, 12-hydroxydodecyl dihydrogen phosphate, 13-hydroxydotridecyl dihydrogen phosphate, 14-hydroxytetradecyl dihydrogen phosphate, 15-hydroxypentadecyl dihydrogen phosphate, 16-hydroxyhexadecyl dihydrogen phosphate, 17-hydroxyheptadecyl dihydrogen phosphate, 18-hydroxyoctadecyl dihydrogen phosphate, 19-hydroxynonadecyl dihydrogen phosphate, 20-hydroxyicosyl dihydrogen phosphate, 3-carboxypropylphosphonic acid, 4-carboxybutylphosphonic acid, 5-carboxypentylphosphonic acid, 6-carboxyhexylphosphonic acid, 7-carboxyheptylphosphonic acid, 8-carboxyoctylphosphonic acid, 9-carboxynonylphosphonic acid, 10-carboxydecylphosphonic acid, 11-carboxyundecylphosphonic acid, 12-carboxydodecylphosphonic acid, 13-carboxydotridecylphosphonic acid, 14-carboxytetradecylphosphonic acid, 15-carboxypentadecylphosphonic acid, 16-carboxyhexadecylphosphonic acid, 17-carboxyheptadecylphosphonic acid, 18-carboxyoctadecylphosphonic acid, 19-carboxynonadecylphosphonic acid, 20-carboxyicosylphosphonic acid, and the like. One type of these compounds may be used alone, or two or more types may be used in combination.

In the case in which the layer (Y) of the multilayer structure contains the organic phosphorus compound (BOb), a ratio MBOb/MBI of a mole number MBOb of the organic phosphorus compound (BOb) to a mole number MBI of the inorganic phosphorus compound (BI) in the layer (Y) preferably satisfies a relation of 1.0×10⁻⁴≤MBOb/MBI≤2.0×10⁻², more preferably satisfies a relation of 3.5×10⁻⁴≤MBOb/MBI≤1.0×10⁻², and still more preferably satisfies a relation of 5.0×10⁻⁴≤MBOb/MBI≤6.0×10⁻³.

In the case in which the layer (Y) contains the organic phosphorus compound (BOb), a C/Al ratio measured by X-ray photoelectron spectroscopy (XPS) at 5 nm from a surface of the layer (Y) of the multilayer structure, the surface not being in contact with the base (X), preferably falls within a range of 0.1 to 15.0, more preferably within a range of 0.3 to 10.0, and particularly preferably within a range of 0.5 to 5.0. When the C/Al ratio in the surface of the layer (Y) falls within the above range, the adhesiveness between the layer (Y) and a layer adjacent thereto may be improved.

### Cross-Linking Agent-Containing Resin Composition (V)

When the layer (Y) contains the cross-linking agent-containing resin composition (V), favorable bending resistance may be obtained. The cross-linking agent-containing resin composition (V) consists of a hydroxyl group-containing resin and a cross-linking agent. Examples of the hydroxyl group-containing resin include a hydroxyl group-containing epoxy resin, a hydroxyl group-containing polyester resin, a hydroxyl group-containing (meth)acrylic resin, a hydroxyl group-containing polyurethane resin, a vinyl alcohol resin, a polysaccharide, and the like; of these, a vinyl alcohol resin or a polysaccharide is preferably contained, a vinyl alcohol resin is more preferably contained, and a polyvinyl alcohol resin is still more preferably contained. As the cross-linking agent, a silicon compound having a glycidyl group, an organic titanium compound, or an organic zirconium compound is suitably used. A mass ratio of the hydroxyl group-containing resin to the cross-linking agent (hydroxyl group-containing resin/cross-linking agent) is preferably 2.0 or more and 200 or less, and more preferably 9.0 or more and 60 or less.

A thickness of the layer (Y) (in a case in which the multilayer structure includes two or more layers (Y), the sum of the thicknesses of the layers (Y)) is preferably 0.05 to 4.0 μm and more preferably 0.1 to 2.0 μm. By reducing the thickness of the layer (Y), a dimensional change of the multilayer structure in processing such as printing, lamination, or the like can be suppressed to be small. Furthermore, since the flexibility of the multilayer structure is increased, the mechanical properties thereof can be brought closer to the mechanical properties of the base itself. In the case in which the multilayer structure of the present invention includes two or more layers (Y), in light of the gas barrier properties, a thickness per layer of the layer (Y) is preferably 0.05 μm or more. The thickness of the layer (Y) can be controlled by the concentration or the coating method of the coating liquid (S) described later which is used in the formation of the layer (Y). The thickness of the layer (Y) can be measured by observing a cross section of the multilayer structure with a scanning electron microscope or a transmission electron microscope.

A surface roughness of the layer (Y) measured by white-light interferometry is preferably 70 nm or less, more preferably 65 nm or less, and still more preferably 60 nm or less. When the surface roughness of the layer (Y) is 70 nm or less, the clarity of the multilayer structure can be further improved. Although details of a procedure for setting the surface roughness of the layer (Y) to 70 nm or less will be described later, it is particularly important to use the base (X) having high image clarity, smoothness, etc. and to apply the coating liquid (S) described later having a viscosity of 400 mPa·s or more and 5,000 mPa·s or less. The surface roughness may be 1 nm or more, 5 nm or more, 10 nm or more, 20 nm or more, or 30 nm or more.

The surface roughness of the layer (Y) is measured as a difference between the highest point and the lowest point in a measurement range of 2.5 mm×2.5 mm by using a scanning white-light interferometric microscope. Furthermore, the surface roughness of the layer (Y) is defined as an average value of measured values in ten measurement ranges.

The surface roughness of the layer (Y) refers to roughness of a face of the layer (Y) adjacent to the base (X), the face being on the side opposite to the base (X). In a case in which the layer (Y) is an outermost layer of the multilayer structure, the surface roughness of the layer (Y) may be roughness of an exposed surface of the layer (Y).

The number of layers (Y) may be one or two or more. When two or more layers (Y) are provided, the barrier properties tend to be improved. In the case in which two or more layers (Y) are provided, a lamination method thereof is not particularly limited; the layers (Y) may be directly disposed on one face or both faces of the base, or multilayer structures each including the layer (Y) may be bonded together with an adhesive layer (I) described later.

### Layer (W)

In the multilayer structure of the present invention, a layer (W) containing at least one selected from the group consisting of the polymer (F), the organic phosphorus compound (BO), and the cross-linking agent-containing resin composition (V) may be directly laminated on the face of the layer (Y), the face being on the side opposite to the base (X). When the layer (W) is provided, the bending resistance may be improved, or the adhesiveness with the adhesive layer (I) described later may be improved. In light of the clarity of the multilayer structure, it may be preferable that the layer (W) is not included.

In the case in which the multilayer structure of the present invention includes the layer (W), the layer (W) is preferably directly laminated on the layer (Y). Suitable modes of the polymer (F), the organic phosphorus compound (BO), and the cross-linking agent-containing resin composition (V), which may be contained in the layer (W), are as described above.

The layer (W) may further contain other component(s), and examples thereof include: inorganic acid metal salts such as carbonate, hydrochloride, nitrate, hydrogen carbonate, sulfate, hydrogen sulfate, and borate; organic acid metal salts such as oxalate, acetate, tartrate, and stearate; metal complexes such as a cyclopentadienyl metal complex (e.g., titanocene) and a cyano metal complex (e.g., Prussian blue); a layered clay compound; a cross-linking agent; a high-molecular compound other than the polymer (BOa) and the polymer (F); a plasticizer; an antioxidant; an ultraviolet absorbing agent; a flame retardant; and the like. A content percentage of the other component(s) in the layer (W) is preferably 20% by mass or less, more preferably 10% by mass or less, still more preferably 5% by mass or less, and may be 2% by mass or less, 1% by mass or less, or 0% by mass (no other component(s) may be contained).

In the case in which the multilayer structure of the present invention includes the layer (W), in light of the fact that the multilayer structure of the present invention can have more favorable bending resistance, a thickness of the layer (W) is preferably 0.005 μm or more. The upper limit of the thickness of the layer (W) is not particularly limited; since the effect of improving the bending resistance is saturated at 1.0 μm or more, it is economically preferable to set the upper limit of the thickness of the layer (W) to 1.0 μm.

### Adhesive Layer (AC)

The multilayer structure of the present invention may include an adhesive layer (AC) between the base (X) and the layer (Y). When the adhesive layer (AC) is provided, the adhesiveness between the base (X) and the layer (Y) may be improved. Particularly in the case in which the base (X) includes the surface layer, the adhesive layer (AC) is preferably provided between the surface layer and the layer (Y), and more preferably, the adhesive layer (AC) is provided on the surface layer which has been subjected to a surface treatment.

An adhesive constituting the adhesive layer (AC) is not particularly limited as long as it has adhesiveness between the base (X) and the layer (Y), and examples of the adhesive include a polyurethane adhesive, a polyester adhesive, and the like. By adding, to the adhesive, a small amount of additive such as a known silane coupling agent or the like, the adhesiveness may be further improved. Examples of the silane coupling agent include silane coupling agents each having a reactive group such as an isocyanate group, an epoxy group, an amino group, a ureido group, a mercapto group, or the like.

A known adhesive may be used as the polyurethane adhesive, and a two-component polyurethane adhesive in which a polyisocyanate component and a polyol component are mixed to react with each other is preferably used. A commercial product such as TAKELAC (registered trademark) or TAKENATE (registered trademark), produced by Mitsui Chemicals, Inc., may be used as the two-component polyurethane adhesive.

A known adhesive may be used as the polyester adhesive, and examples of a commercial product include elitel (registered trademark) KT-0507, KT-8701, KT-8803, KT-9204, KA-5034, KA-3556, KA-1449, KA-5071S, and KZA-1449S (produced by Unitika Ltd.), VYLONAL (registered trademark) MD-1200 and VYLONAL MD-1480 (produced by Toyobo Co., Ltd.), PESRESIN A124GP and PESRESIN A684G (Takamatsu Oil & Fat Co., Ltd.), and the like. When a vinyl alcohol resin, particularly a polyvinyl alcohol, is added to the polyester adhesive, the adhesiveness may be further improved. In a case in which both a vinyl alcohol resin and a polyester resin are used, a mass ratio therebetween (vinyl alcohol resin/polyester resin) is preferably 1/99 or more and 50/50 or less in light of the fact that higher peeling strength can be exhibited while favorable adhesiveness is maintained. In light of the compatibility with the vinyl alcohol resin, the polyester resin is preferably a polyester resin having a carboxyl group. Furthermore, when used as an adhesive, the polyester resin is preferably an aqueous dispersion. When the polyester resin is an aqueous dispersion, the compatibility with the polyvinyl alcohol resin tends to become more favorable. The adhesive layer (AC) preferably has a thickness of 0.001 to 10.0 μm and more preferably 0.01 to 5.0 μm.

### Other Layer (J)

To improve a variety of properties (e.g., heat sealing properties, barrier properties, and mechanical properties), the multilayer structure of the present invention may include an other layer (J). Such a multilayer structure of the present invention can be produced, for example, in such a manner that the layer (Y) is laminated on the base (X) (as necessary, via the adhesive layer (AC)) and the other layer (J) is further adhered or formed directly or via the adhesive layer (I) described later. Examples of the other layer (J) include, but not limited to, an ink layer, a polyolefin layer, a thermoplastic resin layer such as an ethylene-vinyl alcohol copolymer resin layer, and the like.

In the case in which the multilayer structure of the present invention includes the ink layer, the ink layer is exemplified by a film obtained by drying a liquid in which a polyurethane resin containing a pigment (e.g., titanium dioxide) is dispersed in a solvent but may also be a film obtained by drying an ink containing a pigment-free polyurethane resin or another resin as abase resin, or a resist for forming an electronic circuit wiring. Examples of a coating method of the ink layer include a variety of coating methods such as a gravure printing method, a wire bar, a spin coater, a die coater, and the like. The ink layer preferably has a thickness of 0.5 to 10.0 μm and more preferably 1.0 to 4.0 μm.

When a polyolefin layer is used as the outermost layer of the multilayer structure of the present invention, heat sealing properties can be imparted to the multilayer structure, and the mechanical properties of the multilayer structure can be improved. For examples, in light of improving the heat sealing properties and the mechanical properties, the polyolefin is preferably polypropylene or polyethylene. Furthermore, to improve the mechanical properties of the multilayer structure, at least one film selected from the group consisting of a film made of polyester, a film made of polyamide, and a film made of a hydroxyl group-containing polymer is preferably laminated. In light of improving the mechanical properties, the polyester is preferably polyethylene terephthalate, the polyamide is preferably nylon-6, and the hydroxyl group-containing polymer is preferably an ethylene-vinyl alcohol copolymer.

The other layer (J) may be a layer formed by extrusion coating lamination. An extrusion coating lamination method which may be employed in the present invention is not particularly limited, and a known method may be employed. In a typical extrusion coating lamination method, a laminated film is produced in such a manner that a molten thermoplastic resin is supplied to a T die and the thermoplastic resin discharged from a flat slit of the T die is cooled.

Examples of the extrusion coating lamination method include, besides the single lamination method mentioned above, a sandwich lamination method, a tandem lamination method, and the like. The sandwich lamination method is a method in which a molten thermoplastic resin is extruded onto one base, a second base is supplied from another unwinder (unwinding machine), and the bases are bonded together to produce a laminate. The tandem lamination method is a method in which two single laminating machines are connected to produce a five-layer laminate at a time.

### Adhesive Layer (I)

In the multilayer structure of the present invention, the adhesive layer (I) may be used to improve the adhesiveness with an other member (e.g., the other layer (J) or the like). The adhesive layer (I) may consist of an adhesive resin. An adhesive resin for improving the adhesiveness with the other member is preferably a two-component reactive polyurethane adhesive in which a polyisocyanate component and a polyol component are mixed to react with each other. Furthermore, the adhesiveness may be further improved by adding, to an anchor coating agent or an adhesive, a small amount of additive such as a known silane coupling agent or the like. Examples of the silane coupling agent include, but not limited to, silane coupling agents each having a reactive group such as an isocyanate group, an epoxy group, an amino group, a ureido group, a mercapto group, or the like. Owing to the adhesion with the other member, in processing such as printing, lamination, or the like of the multilayer structure of the present invention, deterioration in gas barrier properties or appearance can be more effectively inhibited, and moreover, the drop strength of a packaging material using the multilayer structure of the present invention may be improved.

### Configuration of Multilayer Structure

In the multilayer structure of the present invention, at least the base (X) and the layer (Y) which serve as a pair are laminated to be adjacent to each other. The base (X) and the layer (Y) may be laminated directly or via the adhesive layer (AC); in the case in which the base (X) includes the surface layer and the layer (Y) is provided on the surface layer, the base (X) and the layer (Y) are preferably laminated via the adhesive layer (AC), and in the case in which the base (X) does not include the surface layer, the base (X) and the layer (Y) are preferably directly laminated.

Configuration examples of the multilayer structure of the present invention are shown below; however, the multilayer structure of the present invention is not limited thereto. In each specific example, a plurality of configurations may be combined. Here, “/” means that layers are laminated directly or via an adhesive layer.
(1) Layer (Y)/base (X)
(2) Layer (Y)/base (X)/layer (Y)
(3) Base (X)/layer (Y)/layer (Y)/base (X)
(4) Layer (Y)/base (X)/base (X)/layer (Y)
(5) Layer (Y)/base (X)/layer (Y)/base (X)
(6) Layer (Y)/base (X)/layer (Y)/base (X)/layer (Y)

In the above examples, the base (X) preferably includes a PET layer. Furthermore, the other layer (J) may be further provided; in the case in which the other layer (J) is provided, the other layer (J) may be laminated on the layer (Y), the base (X), or the like via the adhesive layer (I).

### Physical Properties of Multilayer Structure

In the L*a*b* color system of the multilayer structure of the present invention, the a* value and the b* value measured in accordance with JIS Z 8722:2009 are each −0.8 or more, preferably −0.75 or more, and more preferably −0.7 or more. When the a* value and the b* value are less than −0.8, the clarity of the multilayer structure to be obtained tends to decrease. The lower limit value of the a* value and the lower limit value of the b* value may be the same value or different values. Furthermore, the a* value and the b* value are each 0.8 or less, preferably 0.75 or less, and more preferably 0.7 or less. When the a* value and the b* value are greater than 0.8, the clarity of the multilayer structure to be obtained tends to decrease. The upper limit value of the a* value and the upper limit value of the b* value may be the same value or different values. Moreover, a difference between the a* value and the b* value (a* value−b* value) is preferably −1.0 or more and 1.0 or less. When the difference between the a* value and the b* value is 1.0 or more and 1.0 or less, the color is well-balanced, and thus, there is a tendency that a multilayer structure having further superior clarity can be obtained. The a* value and the b* value of the multilayer structure measured in accordance with JIS Z 8722:2009 are each defined as an average value of five measured values.

The multilayer structure of the present invention may satisfy the following condition 1:

### Condition 1:

in a luminance analysis in which reflected light observed when the multilayer structure is moved at a constant speed in a machine direction (MD) in a state in which the multilayer structure is irradiated with light from a white light source is intermittently measured with a line sensor camera; the light from the white light source is delivered to one face of the multilayer structure at an angle of 250 with respect to a vertical direction of the multilayer structure, and the reflected light is measured with the line sensor camera on a face side on which the white light source is provided and at an angle of −30° with respect to the vertical direction of the multilayer structure; and a minimum value of standard deviation of luminance values calculated from values obtained in such a manner that baseline correction is performed on obtained luminance by fitting, by a least-squares method, luminance values within a range of a width (in a transverse direction (TD)) of 12 mm at a center point in the MD of a measurement range is 1.2 or less. In the case in which the multilayer structure satisfies the condition 1 and is used, for example, as a protective sheet for an electronic device, the clarity can be further improved. Although details of a procedure for adjusting such that the multilayer structure satisfies the condition 1 will be described later, it is particularly important that the base (X) has high image clarity and that two seconds after a droplet of 2.0 μL of the coating liquid (S) is dropped at 23° C. and 50% RH onto a treatment face of a polyethylene terephthalate film which has been subjected to a surface treatment at an intensity of 130 W min/m² by using a corona treatment device, a contact angle of the droplet is 200 or more and 350 or less. It is to be noted that the standard deviation of luminance values obtained under the condition 1 may be simply expressed to as “standard deviation of luminance values.”

The minimum value of the standard deviation of luminance values of the multilayer structure of the present invention is preferably 1.2 or less, more preferably 1.1 or less, and still more preferably 1.0 or less. When the minimum value of the standard deviation of luminance values is 1.2 or less, the clarity of the multilayer structure tends to be further improved. The standard deviation of luminance values may be 0.6 or more.

### Method for Evaluating Standard Deviation of Luminance of Multilayer Structure

In the multilayer structure of the present invention, the standard deviation of luminance can be evaluated by the following method.

### 1. Measurement

The light from the white light source is delivered at an angle of 250 with respect to the vertical direction of the multilayer structure. Next, the line sensor camera is set on the face side on which the white light source is provided and at an angle of −30° with respect to the vertical direction of the multilayer structure, and then adjusted to be focused on the multilayer structure. The multilayer structure is moved at a constant speed in the MD, and the luminance of the reflected light observed during the movement is intermittently measured with the line sensor camera.

### 2. Analysis

With regard to the obtained luminance, the luminance values within the range of the width (in a transverse direction (TD)) of 12 mm at the center point in the MD of the measurement range are fit with a quadratic function by the least-squares method. The baseline correction is performed using the obtained data as a baseline to calculate differences between the values obtained by fitting by the least-squares method and the measured values. The minimum value of the standard deviation of the luminance after the baseline correction is defined as standard deviation of the luminance of the multilayer structure. This analysis enables evaluating a luminance difference in a film caused by fine mottle or the like which is difficult to visually recognize.

A water vapor transmission rate of the multilayer structure of the present invention is preferably 1×10⁻² g/m²·day or less, more preferably 9×10⁻³ g/m²·day or less, and still more preferably 7×10⁻³ g/m²·day or less as measured at 40° C. and 90% RH in accordance with ISO 15106-3:2003. When the water vapor transmission rate is 1×10⁻² g/m²·day or less, an item obtained using the multilayer structure (e.g., a protective sheet for an electronic device) tends to be superior in moisture barrier properties and less likely to deteriorate even in severe environments.

An oxygen transmission rate of the multilayer structure of the present invention measured at 20° C. and 85% RH in accordance with ISO 15105-2:2003 is preferably 7×10⁻² cc/m²·day·atm or less, more preferably 5×10⁻² cc/m²·day·atm or less, and still more preferably 2×10⁻² cc/m²·day·atm or less. When the oxygen transmission rate is 7×10⁻² cc/m²·day atm or less, an item obtained using the multilayer structure to be obtained (e.g., a protective sheet for an electronic device) tends to be superior in oxygen barrier properties and less likely to deteriorate even in severe environments.

### Method for Producing Multilayer Structure

The description of the multilayer structure of the present invention can be applied to a production method of the present invention; therefore, repetitive description may be omitted. Furthermore, the description of the production method of the present invention can be applied to the multilayer structure of the present invention.

An example of the method for producing the multilayer structure of the present invention is a production method including: a step (I) of forming a precursor layer of the layer (Y) by applying, onto the base (X), the coating liquid (S) containing the metal oxide (A), the inorganic phosphorus compound (BI), and a solvent, followed by removing the solvent; and a step (II) of forming the layer (Y) by subjecting the precursor layer of the layer (Y) to a heat treatment. In a case in which a multilayer structure containing the organic phosphorus compound (BO) or the polymer (F), the coating liquid (S) used in the step (I) may contain the organic phosphorus compound (BO) or the polymer (F) to form the layer (Y) containing the organic phosphorus compound (BO) or the polymer (F); a coating liquid (T) containing the organic phosphorus compound (BO) or the polymer (F) may be prepared, and in a step (III) of coating, with the coating liquid (T), a surface of the precursor layer of the layer (Y) obtained in the step (I) or a surface of the layer (Y) obtained in the step (II), the layer (Y) may be impregnated with the organic phosphorus compound (BO) or the polymer (F); or the layer (W) may be provided on the layer (Y). It is to be noted that in a case in which the adhesive layer (AC) is provided between the base (X) and the layer (Y), a step of providing the adhesive layer (AC) on the base (X) may be included before the step (I).

### Step (I)

In the step (I), the precursor layer of the layer (Y) is formed by applying, onto the base (X), the coating liquid (S) containing the metal oxide (A), the inorganic phosphorus compound (BI), and the solvent, followed by removing the solvent.

The coating liquid (S) can be obtained by mixing the metal oxide (A), the inorganic phosphorus compound (BI), and the solvent. Examples of a specific means for preparing the coating liquid (S) include: a method in which a dispersion of the metal oxide (A) and a solution containing the inorganic phosphorus compound (BI) are mixed; a method in which the inorganic phosphorus compound (BI) is added to and mixed with a dispersion of the metal oxide (A); and the like. The temperature at the time of mixing is preferably 50° C. or less, more preferably 30° C. or less, and still more preferably 20° C. or less. The coating liquid (S) may contain other compound(s) (e.g., the organic phosphorus compound (BO) and/or the polymer (F)) and, as necessary, at least one acid compound (Q) selected from the group consisting of acetic acid, hydrochloric acid, nitric acid, trifluoroacetic acid, and trichloroacetic acid.

The dispersion of the metal oxide (A) can be prepared, for example, in such a manner that in accordance with a procedure employed in a known sol-gel method, for example, the compound (E), water, and as necessary, an acid catalyst and/or an organic solvent are mixed and then the compound (E) is condensed or hydrolytically condensed. In the case in which the dispersion of the metal oxide (A) is obtained by condensing or hydrolytically condensing the compound (E), as necessary, certain treatment (deflocculation in the presence of the acid compound (Q) or the like) may be performed on the obtained dispersion. A solvent used in the preparation of the dispersion of the metal oxide (A) is not particularly limited and is preferably an alcohol such as methanol, ethanol, or isopropanol, water, or a mixed solvent thereof.

A solvent used in the solution containing the inorganic phosphorus compound (BI) may be appropriately selected in accordance with the type of the inorganic phosphorus compound (BI) and preferably contains water. The solvent may contain an organic solvent (e.g., an alcohol such as methanol or the like) unless dissolution of the inorganic phosphorus compound (BI) is hindered.

In light of the storage stability of the coating liquid (S) and its coating properties with respect to the base, the coating liquid (S) preferably has a solid content concentration of 1 to 20% by mass, more preferably 2 to 15% by mass, and still more preferably 3 to 10% by mass. The solid content concentration can be calculated, for example, by dividing the mass of a solid content remaining after distilling away the solvent of the coating liquid (S) by the mass of the coating liquid (S) used in the treatment.

With regard to the coating liquid (S), a viscosity (I) measured with a Brookfield rotational viscometer (SB viscometer: rotor No. 3; rotational speed: 60 rpm) at a coating temperature is preferably 3,000 mPa·s or less, more preferably 2,500 mPa·s or less, and still more preferably 2,000 mPa·s or less. When the viscosity (I) is 3,000 mPa·s or less, the leveling properties of the coating liquid (S) can be improved, and thus, a multilayer structure having further superior appearance can be obtained. Furthermore, the viscosity (I) of the coating liquid (S) is preferably 50 mPa·s or more, more preferably 100 mPa·s or more, and still more preferably 200 mPa·s or more.

With regard to the coating liquid (S), in light of reducing the surface roughness of the layer (Y) to 70 nm or less, a viscosity (II) measured with a Brookfield rotational viscometer (SB viscometer: spindle No. 63; rotational speed: 6 rpm) at a coating temperature is preferably 5,000 mPa·s or less, more preferably 4,500 mPa·s or less, and still more preferably 4,000 mPa·s or less. Furthermore, the viscosity (II) of the coating liquid (S) is preferably 400 mPa·s or more, more preferably 600 mPa·s or more, and still more preferably 800 mPa·s or more. When the viscosity is 400 mPa·s or more, the barrier properties tend to be improved.

In the coating liquid (S), a molar ratio of an aluminum atom to a phosphorus atom preferably falls within a range of [aluminum atom:phosphorus atom]=1.0:1.0 to 3.6:1.0, more preferably within a range of 1.1:1.0 to 3.0:1.0, and particularly preferably within a range of 1.11:1.00 to 1.50:1.00. The molar ratio of an aluminum atom to a phosphorus atom can be calculated by performing a fluorescent x-ray analysis of a dried product of the coating liquid (S).

The coating liquid (S) preferably satisfies the following condition 2:

### Condition 2:

two seconds after a droplet of 2.0 μL of the coating liquid (S) is dropped at 23° C. and 50% RH onto a treatment face of a polyethylene terephthalate film which has been subjected to a surface treatment at an intensity of 130 W min/m² by using a corona treatment device, a contact angle of the droplet is 200 or more and 350 or less.

In the case in which the coating liquid (S) satisfies the condition 2, the multilayer structure to be obtained can easily satisfy the condition 1. The contact angle is preferably 330 or less and more preferably 310 or less. When the contact angle is 350 or less, the leveling properties of the coating liquid (S) can be improved, and thus, there is a tendency that a multilayer structure having further superior clarity can be obtained. Furthermore, the contact angle is preferably 220 or more and more preferably 250 or more. When the contact angle is 200 or more, the barrier properties tend to be further improved.

A method for adjusting the contact angle to 200 or more and 350 or less is not particularly limited, and can be achieved, for example, by selecting the solvent of the coating liquid (S).

The solvent of the coating liquid (S) is not particularly limited and is, in light of the coating properties, preferably an alcohol such as methanol, ethanol, or isopropanol, water, or a mixed solvent thereof, more preferably a mixed solvent of water and an alcohol, and still more preferably a mixed solvent of water and methanol. With regard to a mixed solvent ratio between water and methanol, a water/methanol ratio is preferably 3.5/6.5 or more and 7/3 or less. When the water/methanol ratio is 7/3 or less, the contact angle tends to be adjustable to 200 or more and 350 or less. Furthermore, when the water/methanol ratio is 3.5/6.5 or more, there is a tendency that the coating liquid (S) which is uniform can be produced.

The coating with the coating liquid (S) is not particularly limited and may be performed by a known method. Examples of the coating method include a casting method, a dipping method, a roll coating method, a gravure coating method, a screen printing method, a reverse coating method, a spray coating method, a kiss coating method, a die coating method, a metaling bar coating method, a chamber doctor combined coating method, a curtain coating method, a bar coating method, and the like.

A method for removing the solvent after the coating with the coating liquid (S) (drying treatment) is not particularly limited, and a known drying method may be applied. Examples of the drying method include a hot-air drying method, a hot roll contact method, an infrared heating method, a microwave heating method, and the like.

The drying temperature is preferably lower than a flow start temperature of the base (X). The drying temperature after the coating with the coating liquid (S) is 120° C. or more, may be 120° C. or more and less than 180° C., is more preferably 120° C. or more and less than 165° C., still more preferably 120° C. or more and less than 150° C., and particularly preferably 120° C. or more and less than 140° C. The drying time is not particularly limited, is preferably 1 sec or more and less than 1 hr, and may be 5 sec or more and less than 15 min or 5 sec or more and less than 300 sec. Furthermore, the drying time may be 1 sec or more and less than 4 min, 5 sec or more and less than 4 min, or 5 sec or more and less than 3 min. When the conditions for the drying treatment of the coating liquid (S) fall within the above ranges, a multilayer structure having more favorable gas barrier properties tends to be obtained. When the solvent is removed through the drying, the precursor layer of the layer (Y) is formed.

The time period from the completion of the coating with the coating liquid (S) to the start of the drying by heating is 1.8 sec or more, preferably 2.3 sec or more, and more preferably 3.0 sec or more. When the time period from the completion of the coating to the start of the drying by heating is 1.8 sec or more, the leveling properties of the coating liquid (S) can be improved, and thus, there is a tendency that a multilayer structure having further superior clarity can be obtained. Furthermore, the time period from the completion of the coating to the start of the drying by heating is 9.0 sec or less, preferably 8.5 sec or less, and more preferably 8.0 sec or less. When the time period from the completion of the coating to the start of the drying by heating is 9.0 sec or less, the coated face tends to be uniform, and thus, the barrier properties tend to be improved. It is to be noted that when the time period from the coating to the drying is less than 1.8 sec, the a* value and the b* value are not −0.8 or more and 0.8 or less; when the time is greater than 9.0 sec, it tends to be difficult to form the multilayer structure. For example, in a case which the multilayer structure of the present invention is continuously produced, the time period from the completion of the coating to the start of the drying by heating as referred to herein means the time directly after the coating with the coating liquid (S) until the coated portion enters an atmosphere at 120° C. or more (until it enters a drying furnace at 120° C. or more).

In the case in which the layers (Y) are laminated on both faces of the base (X), typically, the coating liquid (S) is applied onto one face of the base (X), and then the solvent is removed to form a first layer (a precursor layer of a first layer (Y)), next, the coating liquid (S) is applied onto the other face of the base (X), and then the solvent is removed to form a second layer (a precursor layer of a second layer (Y)). The compositions of the coating liquids (S) applied to the respective faces may be the same or different from each other.

### Step (II)

In the step (II), the layer (Y) is formed by subjecting the precursor layer of the layer (Y) to a heat treatment formed in the step (I). In the step (II), a reaction in which the reaction product (D) is generated proceeds. To sufficiently proceed the reaction, a heat treatment temperature is preferably 140° C. or more, more preferably 170° C. or more, still more preferably 180° C. or more, and particularly preferably 190° C. or more. When the heat treatment temperature is low, time for obtaining a sufficient reaction rate may be prolonged, which may cause a decrease in productivity. The heat treatment temperature varies depending on the type of the base (X) or the like; for example, in a case in which a thermoplastic resin film made of a polyamide resin is used as the base (X), the heat treatment temperature is preferably 270° C. or less. Furthermore, in a case in which a thermoplastic resin film made of a polyester resin is used as the base (X), the heat treatment temperature is preferably 240° C. or less. The heat treatment may be performed in an air atmosphere, a nitrogen atmosphere, an argon atmosphere, or the like. The heat treatment time is preferably 1 sec to 1 hr, more preferably 1 sec to 15 min, and still more preferably 5 to 300 sec.

The step (II) preferably includes a first heat treatment step (II-1) and a second heat treatment step (II-2). In the case in which the heat treatment is performed in two or more stages, the temperature of a second-stage heat treatment (hereinafter, second heat treatment) is preferably higher than the temperature of a first-stage heat treatment (hereinafter, first heat treatment), more preferably higher than the temperature of the first heat treatment by 15° C. or more, still more preferably higher by 20° C. or more, and particularly preferably higher by 30° C. or more.

Furthermore, in light of the fact that a multilayer structure having favorable properties can be obtained, the heat treatment temperature in the step (II) (in the case in which the heat treatment includes two or more stages, the temperature of the first heat treatment) is preferably higher than the drying temperature in the step (I), preferably higher by 30° C. or more, more preferably higher by 50° C. or more, still more preferably higher by 55° C. or more, and particularly preferably higher by 60° C. or more.

In the case in which the heat treatment in the step (II) is performed in two or more stages, the temperature of the first heat treatment is preferably 140° C. or more and less than 200° C., and more preferably, the temperature of the second heat treatment is 180° C. or more 270° C. or less; the temperature of the second heat treatment is preferably higher than the temperature of the first heat treatment, more preferably higher by 15° C. or more, and still more preferably higher by 25° C. or more. Particularly in a case in which the heat treatment temperature is 200° C. or more, the heat treatment time is preferably 0.1 sec to 10 min, more preferably 0.5 sec to 5 min, and still more preferably 1 sec to 3 min. In a case in which the heat treatment temperature is lower than 200° C., the heat treatment time is preferably 1 sec to 15 min, more preferably 5 sec to 10 min, and still more preferably 10 sec to 5 min.

### Step (III)

In a case in which the organic phosphorus compound (BO), the polymer (F), and/or the other component(s) are used in the production method, the production method may include the step (III) in which the coating liquid (T) obtained by mixing the organic phosphorus compound (BO), the polymer (F), and/or the other component(s), and the solvent is applied onto the precursor layer of the layer (Y) obtained in the step (I), the layer (Y) obtained in the step (II), or the precursor layer of the layer (Y) after the step (II-1), and then a drying treatment is performed. In the case in which the step (III) is performed after the step (II-1), the step (II-2) is preferably performed after the drying treatment in the step (III). In the step (III), the layer (W) may be formed on the layer (Y) by increasing the amount of the coating liquid (T) applied.

The solvent used in the coating liquid (T) may be appropriately selected in accordance with the type of the organic phosphorus compound (BO), the polymer (F), and/or the other component(s) and is preferably an alcohol such as methanol, ethanol, or isopropanol, water, or a mixed solvent thereof.

In light of the storage stability and the coating properties of the solution, a solid content concentration in the coating liquid (T) is preferably 0.01 to 60% by mass, more preferably 0.1 to 50% by mass, and still more preferably 0.2 to 40% by mass. The solid content concentration can be determined by a method similar to the method in the description of the coating liquid (S).

Similarly to the coating with the coating liquid (S), a coating method of the coating liquid (T) is not particularly limited, and a known method may be employed.

As conditions for a method for removing the solvent after the coating with the coating liquid (T) in the step (III) (drying treatment), those similar to the conditions for the drying treatment after the coating with the coating liquid (S) in the step (I) can be applied.

### Step (IV)

Before the step (I), a step of providing the adhesive layer (AC) on the base (X) which has been subjected to a surface treatment as necessary may be included. More preferably, a step (IV) of forming the adhesive layer (AC) by applying, onto the base (X), a coating liquid (R) containing a PVA resin, a polyester resin, and a solvent, followed by removing the solvent may be included.

As a means for obtaining the coating liquid (R), for example, the PVA resin, the polyester resin, and the solvent may be directly mixed, or a solution or dispersion containing the PVA resin may be mixed with a solution or dispersion containing the polyester resin. Of these, in light of the uniformity of the solution, the coating liquid (R) is preferably obtained by mixing an aqueous solution of the PVA resin and a dispersion of the polyester resin.

The solvent used in the coating liquid (R) is not particularly limited, preferably contains water as a principle component, and may be only water. Furthermore, as another solvent used in the case in which water is the principle component, an alcohol such as methanol, ethanol, or isopropanol is preferably used.

In light of the storage stability of the coating liquid (R) and its coating properties with respect to the base, a solid content concentration of the coating liquid (R) is preferably 0.01 to 10% by mass. The solid content concentration can be calculated, for example, by dividing the mass of a solid content remaining after distilling away the solvent of the coating liquid (R) by the mass of the coating liquid (R) used in the treatment.

The coating with the coating liquid (R) is not particularly limited, and a known method may be employed. Examples of the coating method include a casting method, a dipping method, a roll coating method, a gravure coating method, a screen printing method, a reverse coating method, a spray coating method, a kiss coating method, a die coating method, a metaling bar coating method, a chamber doctor combined coating method, a curtain coating method, a bar coating method, and the like.

A method for removing the solvent of the coating liquid (R) after the coating of the base (X) is not particularly limited, and a known drying method may be applied. Examples of the drying method include a hot-air drying method, a hot roll contact method, an infrared heating method, a microwave heating method, and the like.

### Protective Sheet for Electronic Device

A protective sheet for an electronic device of the present invention includes the multilayer structure of the present invention. The protective sheet for an electronic device of the present invention may consist of only the multilayer structure of the present invention or may consist of the multilayer structure of the present invention and other member(s). The protective sheet for an electronic device of the present invention can be used, for example, as a protective sheet for protecting a surface of a photoelectric conversion device, an information display device, or a lighting device. The protective sheet for an electronic device of the present invention has high barrier properties and clarity. Therefore, by using the protective sheet of the present invention, an electronic device which is less deteriorated even in severe environments and has high clarity of a transmission image can be obtained. For example, in a case in which the protective sheet is used as a substrate film for electronic paper, the protective sheet can be suitably used as a protector for ink of the electronic paper, which is susceptible to moisture.

The protective sheet for an electronic device of the present invention may include a surface protective layer disposed on one surface of the multilayer structure. The surface protective layer is preferably a layer made of a highly transparent and scratch-resistant resin. Furthermore, a surface protective layer of a device which may be used outdoors, such as a solar cell, is preferably made of a weather-resistant (e.g., light-resistant) resin. Furthermore, in a case of protecting a face which needs to transmit light, a surface protective layer having high light-transmitting properties is preferred. Examples of a material of the surface protective layer (surface protective film) include an acrylic resin, polycarbonate, polyethylene terephthalate, polyethylene naphthalate, triacetyl cellulose, a cycloolefin polymer, an ethylene-tetrafluoroethylene copolymer (ETFE), polytetrafluoroethylene, a 4-ethylene fluoride-perchloroalkoxy copolymer, a 4-ethylene fluoride-6-propylene fluoride copolymer, a 2-ethylene-4-ethylene fluoride copolymer, poly-3-fluoroethylene chloride, polyvinylidene fluoride, polyvinyl fluoride, and the like.

To enhance the durability of the surface protective layer, a variety of additives (e.g., an ultraviolet absorbing agent) may be added to the surface protective layer. A preferred example of a weather-resistant surface protective layer is an acrylic resin layer to which an ultraviolet absorbing agent is added. Examples of the ultraviolet absorbing agent include, but not limited to, benzotriazole-based, benzophenone-based, salicylate-based, cyanoacrylate-based, nickel-based, and triazine-based ultraviolet absorbing agents. Furthermore, a stabilizer, a light stabilizer, an antioxidant, or the like may also be used in combination.

Moreover, to enhance the durability of the surface protective layer, a surface thereof may be subjected to weather-resistant coating such as hard coating or the like. The type of the coating is not particularly limited, and a known material may be used.

The configuration of the protective sheet is not particularly limited, and for example, the following configurations may be suitably used:
(1) multilayer structure;
(2) multilayer structure/adhesive layer/polyethylene terephthalate;
(3) multilayer structure/adhesive layer/triacetyl cellulose;
(4) multilayer structure/adhesive layer/acrylic;
(5) multilayer structure/adhesive layer/polycarbonate;
(6) multilayer structure/adhesive layer/cycloolefin polymer; and
(7) ETFE layer/adhesive layer/multilayer structure.

The multilayer structure of the present invention can also be used as a film called a substrate film, such as an LCD substrate film, an organic EL substrate film, an electronic paper substrate film, or the like. In this case, the multilayer structure may serve both as a substrate and a protective sheet. Furthermore, the electronic device which is to be protected by the protective sheet is not limited to the above examples and may be, for example, an IC tag, an optical communication device, a fuel battery, or the like.

### Electronic Device

An electronic device using the multilayer structure of the present invention typically includes: an electronic device main body; and a protective sheet for protecting a surface of the electronic device main body. The protective sheet is the above-described protective sheet for an electronic device of the present invention.

The electronic device of the present invention may be a photoelectric conversion device, an information display device, or a lighting device. Examples of the photoelectric conversion device include a variety of solar cells and other photoelectric conversion devices. Examples of the information display device include a liquid crystal display, an organic EL display, a plasma display, electronic paper, and other information display devices. Examples of the lighting device include an LED lighting, an organic EL lighting, and other lighting devices.

The electronic device of the present invention can be particularly preferably used as a device including an optical element. The optical element is appropriately selected in accordance with the application of the electronic device of the present invention. As referred to herein, the optical element in the present invention refers to an element having an optical function, and examples of the optical function include an information display function, a light-emitting function, and the like. In a case in which an element having an information display function is used as the optical element, the electronic device of the present invention can be used as an information display device; in a case in which an element having a light-emitting function is used as the optical element, the electronic device of the present invention can be used as a light-emitting device (lighting device).

Examples of the optical element having an information display function include a liquid crystal cell used in a liquid crystal display device, an organic EL element used in an organic EL display device, an electronic paper element (of a particle movement type, a liquid crystal type, an electrochemical type, etc.) used in an electronic paper device, and the like. In this regard, when a liquid crystal cell is used as the optical element, a liquid crystal display device is obtained as the optical device of the present invention; when an organic EL element is used, an organic EL display device is obtained; furthermore, when an electronic paper element is used, an electronic paper device is obtained.

The liquid crystal cell, the organic EL element, and the electronic paper element are not particularly limited, and generally known elements may be used.

### EXAMPLES

Next, the present invention will be more specifically described by way of Examples; however, the present invention is not limited to these Examples, and those with ordinary knowledge in this field can make various modifications within the scope of the technical concept of the present invention. Analysis and evaluation in the following Examples and Comparative Examples were performed in the following manner.

### Materials Used in Examples and Comparative Examples

PET50: biaxially stretched polyethylene terephthalate film; “Lumirror (trademark) U403” (product name), produced by Toray Industries, Inc., including surface layers on both faces and having a thickness of 50 μm and an image clarity of 94%
PET23-A: biaxially stretched polyethylene terephthalate film; “Lumirror (trademark) U403” (product name), produced by Toray Industries, Inc., including surface layers on both faces and having a thickness of 23 μm and an image clarity of 94%
PET23-B: biaxially stretched polyethylene terephthalate film; “DIAFOIL (trademark) T600E” (product name), produced by Mitsubishi Chemical Corporation, including a surface layer on one face and having a thickness of 23 μm and an image clarity of 94%
PET23-C: biaxially stretched polyethylene terephthalate film; “RH210” (product name), produced by HYOSUNG Corporation, including surface layers on both faces and having a thickness of 23 μm and an image clarity of 94%
PET23-D: biaxially stretched polyethylene terephthalate film; “Lumirror (trademark) S105” (product name), produced by Toray Industries, Inc., having a thickness of 23 μm and an image clarity of 83%
PET38: biaxially stretched polyethylene terephthalate film; “Lumirror (trademark) U483” (product name), produced by Toray Industries, Inc., including surface layers on both faces and having a thickness of 38 μm and an image clarity of 94%
PET75: biaxially stretched polyethylene terephthalate film; “Lumirror (trademark) U483” (product name), produced by Toray Industries, Inc., including surface layers on both faces and having a thickness of 75 μm and an image clarity of 93%
PET12: biaxially stretched polyethylene terephthalate film; “Lumirror (trademark) P60” (product name), produced by Toray Industries, Inc., having a thickness of 12 μm and an image clarity of 82%

The image clarity was measured in accordance with a method disclosed in Evaluation Method (4) described later.

### Evaluation Method

### (1) Measurement of Maximum Absorption Wavenumber (Imax) of Infrared Absorption Spectrum

The layer (Y) of each of multilayer structures obtained in Examples and Comparative Examples was measured with a Fourier transform infrared spectrophotometer by an attenuated total reflection method, and a maximum absorption wavenumber (Imax) in the region of 800 to 1,400 cm⁻¹ was calculated. The measurement conditions were as follows.
Device: Spectrum One, produced by PerkinElmer, Inc.
Measurement mode: attenuated total reflection method
Measurement region: 800 to 1,400 cm⁻¹

### (2) Thickness

Each of the multilayer structures obtained in Examples and Comparative Examples was cut with a focused ion beam (FIB) to produce a section for cross sectional observation. The produced section was fixed to a sample pedestal with carbon tape, and platinum ion sputtering was performed at an acceleration voltage of 30 kV for 30 sec. A cross section of the multilayer structure was observed with a field-emission transmission electron microscope, and the thickness of each layer and the thickness of the multilayer structure were calculated. The measurement conditions were as follows.
Device: JEM-2100F, produced by JEOL Ltd.
Acceleration voltage: 200 kV
Magnification: 250,000

### (3) Water Vapor Transmission Rate

Each of the multilayer structures obtained in Examples and Comparative Examples was set on a water vapor transmission measuring device, and the water vapor transmission rate was measured by an equal pressure method in accordance with ISO 15106-3:2003. The measurement conditions were as follows. In a case of a water vapor transmission rate of 1×10⁻² g/(m²·day) or less, the multilayer structure was determined to have high water vapor barrier properties.
Device: AQUATRAN, produced by MOCON, Inc.
Temperature: 40° C.
Humidity on water vapor supply side: 90% RH

### (4) Image Clarity

The base (X) used in each of Examples and Comparative Examples was set on an image clarity measuring device, and the image clarity was measured in accordance with ISO 17221. The measurement conditions were as follows, and an average value of five measurements was employed as a measured value.
Device: image clarity meter IC-T, produced by Suga Test Instruments Co., Ltd.
Optical comb width: 0.25 mm

### (5) Clarity

Each of electronic-device protective sheets obtained in Examples and Comparative Examples was put on a surface of an image display device such that the laminated material was on the front side, and it was evaluated whether characters displayed on the image display device could be clearly seen. The case in which the characters were clearly displayed was rated as A, the case in which edges of the characters were slightly blurred was rated as B, and the case in which the characters were entirely blurred was rated as C; ten panelists made evaluations, and the most dominant rating was defined as evaluation of the clarity. It is to be noted that if there were a plurality of the most dominant ratings, all the plurality of ratings were listed.

### (6) Oxygen Transmission Rate

Each of the multilayer structures obtained in Examples and Comparative Examples was cut into a size of 10 mm×10 mm. The multilayer structure which had been cut out was set on an oxygen transmission measuring device, and the oxygen transmission rate was measured by an equal pressure method. The measurement conditions were as follows. When the oxygen transmission rate was 0.07 cc/(m²·day·atm) or less, the oxygen barrier properties were determined to be high.
Device: OX-TRAN2/21, produced by MOCON, Inc.
Temperature: 20° C.
Humidity on oxygen supply side: 85% RH
Humidity on carrier gas side: 85% RH
Carrier gas flow rate: 10 mL/min
Oxygen pressure: 1.0 atm
Carrier gas pressure: 1.0 atm

### (7) Color

Each of the multilayer structures obtained in Examples and Comparative Examples was set on a spectrophotometer, and a* and b* were evaluated in accordance with JIS Z 8722:2009. The measurement was performed five times, and an average value was employed as a measured value.
Device: spectrophotometer U-4100, produced by Hitachi High-Tech Corporation
Light source: C light source

### Production Example of Coating Liquid (S-1)

While stirring, 230 parts by mass of distilled water was heated to 70° C. Hydrolytic condensation was performed in such a manner that 88 parts by mass of triisopropoxyaluminum was dropped into the distilled water over the course of 1 hr, and the liquid temperature was gradually raised to 95° C. to distill generated isopropanol. To the obtained liquid, 4.0 parts by mass of a 60% by mass nitric acid aqueous solution was added, and the resulting mixture was stirred at 95° C. for 3 hrs to deflocculate an aggregate of particles of the hydrolyzed condensate. After that, the liquid was condensed to have a solid content concentration of 10% by mass in terms of aluminum oxide, whereby a solution was obtained. To 22.50 parts by mass of the solution thus obtained, 54.29 parts by mass of distilled water was added, and the resulting mixture was uniformly stirred to obtain a dispersion. Subsequently, while the dispersion was stirred in a state in which the liquid temperature was maintained at 15° C., 4.41 parts by mass of an 85% by mass phosphoric acid aqueous solution was dropwise added. Moreover, 18.80 parts by mass of a methanol solution was dropwise added, and the stirring was continued at 15° C. until the viscosity reached 1,500 mPa·s, whereby a target coating liquid (S-1) was obtained. The molar ratio of an aluminum atom to a phosphorus atom in the coating liquid (S-1) was aluminum atom:phosphorus atom=1.15:1.00. It is to be noted that the viscosity of the coating liquid (S-1) is a value measured with a Brookfield rotational viscometer (SB viscometer: rotor No. 3; rotational speed: 60 rpm).

### Production Example of Coating Liquid (R-1)

A PVA aqueous solution was obtained in such a manner that 4.8 parts by mass of a PVA “KURARAY POVAL (registered trademark) 48-80” and 95.2 parts by mass of water were mixed and stirred at room temperature for 5 hrs to dissolve “KURARAY POVAL (registered trademark) 48-80.” Next, 0.8 parts by mass of a polyester aqueous dispersion “elitel (registered trademark) KA-507IS” (produced by Unitika Ltd.), 1.2 parts by mass of the PVA aqueous solution, 68.1 parts by mass of water, and 29.9 parts by mass of methanol were mixed and stirred for 1 hr to obtain a coating liquid (R-1).

### Example 1

The PET50 was used as a base (X-1), one face of the base (X-1) was subjected to a surface treatment by a corona treatment at an intensity of 130 W min/m² and then continuously coated with the coating liquid (R-1) by a gravure coating method such that the thickness after drying was 10 nm, drying was performed in a hot-air drying furnace at 140° C., and then, the resulting film was wound into a roll to form an adhesive layer (AC-1) on the one face of the base. The adhesive layer (AC-1) formed was continuously coated with the coating liquid (S-1) by a gravure coating method such that the thickness after drying was 0.4 μm and the time period from the completion of the coating to the start of the drying was 4.1 sec, drying was performed in a hot-air drying furnace at 120° C., and then, the resulting film was wound into a roll to form a precursor layer of a layer (Y-1). It is to be noted that the time period from the coating to the start of the drying was defined as a time period from the completion of the coating with the coating liquid (S-1) to a moment at which the multilayer structure enters the hot-air drying furnace. Next, the other face of the base (X-1) was also subjected to a surface treatment by the same procedure, and then, the adhesive layer (AC-1) and the precursor layer of the layer (Y-1) were formed in this order. The obtained film in which the precursor layer of the layer (Y-1) was formed was subjected to a heat treatment at 180° C. for 1 min by passing through a hot-air drying furnace and then wound into a roll. Moreover, the obtained film in which the precursor layer of the layer (Y-1) was formed was subjected to a heat treatment at 210° C. for 1 min by passing through a hot-air drying furnace to obtain a multilayer structure having a configuration of layer (Y-1) (0.4 μm)/adhesive layer (AC-1) (10 nm)/base (X-1) (50 μm)/adhesive layer (AC-1) (10 nm)/layer (Y-1) (0.4 μm). The layer (Y-1) of the obtained multilayer structure was evaluated by the methods disclosed in Evaluation Methods (1) and (2). Furthermore, the obtained multilayer structure was evaluated by the methods disclosed in Evaluation Methods (3), (6), and (7). The results are shown in Table 1.

Six pieces of the obtained multilayer structure were prepared, an adhesive layer was formed on one face of each multilayer structure by using a two-component polyurethane adhesive (“TAKELAC (registered trademark) A-1102,” produced by Mitsui Chemicals, Inc., and “TAKENATE (registered trademark) A-3070,” produced by Mitsui Chemicals, Inc.), and materials shown below were laminated on the respective adhesive layers to produce six types of electronic-device protective sheets. The clarity of each of the obtained electronic-device protective sheets was evaluated by the method disclosed in Evaluation Method (5). The results are shown in Table 1. It is to be noted that clarities 1 to 6 in Table 1 respectively mean evaluations of the following materials 1 to 6 and the laminated electronic-device protective sheets.
1. Lumirror (trademark) U403 (produced by Toray Industries, Inc.; thickness: 50 μm)
2. COSMOSHINE SRF (trademark) (produced by TOYOBO Co., Ltd.; thickness: 80 μm)
3. triacetyl cellulose (TAC) film (produced by Konica Minolta, Inc.; thickness: 80 μm)
4. OXIS (trademark) PMMA (produced by Okura Industrial Co., Ltd.; thickness: 40 μm)
5. polycarbonate film, PURE-ACE (trademark) (produced by Teijin Limited; thickness: 70 μm)
6. ZeonorFilm (trademark) (produced by Zeon Corporation; thickness: 70 μm)

Examples 2 to 6 and Comparative Examples 3 and 4 Multilayer structures and electronic-device protective sheets were produced and evaluated by the same procedures as in Example 1, except that the base (X) shown in Table 1 was used instead of the PET50 used in Example 1. The results are shown in Table 1.

### Example 7

A multilayer structure and an electronic-device protective sheet were produced and evaluated in the same manner as in Example 1, except that the one face of the PET50 used in Example 1 was not subjected to the surface treatment and not provided with the adhesive layer (AC-1) or the layer (Y-1) so that a multilayer structure having a configuration of layer (Y-1) (0.4 μm)/adhesive layer (AC-1) (10 nm)/(surface treatment face) base (X-1) (50 μm) (non-surface treatment face) was produced. The results are shown in Table 1.

### Examples 8 and 9 and Comparative Examples 1 and 2

Multilayer structures and electronic-device protective sheets were produced and evaluated by the same procedures as in Example 1, except that the time period from the completion of the coating with the coating liquid (S-1) to the start of the drying was changed as shown in Table 1. The results are shown in Table 1.

TABLE 1

| | | | Layer (Y) | | | | | |
|---|---|---|---|---|---|---|---|---|
| | | | | | time period | Multilayer | | |
| | Base (X) | | | | from | structure | Evaluation | |
| | | image | thick- | | coating to | layer | color | |
| | | clarity | ness | Imax | drying | con- | a* | b* |
| | type | % | μm | cm⁻¹ | s | figuration | — | — |
| Example 1 | PET50 | 94 | 0.4 | 1,108 | 4.1 | (Y)/(X)/(Y) | 0.14 | −0.22 |
| Example 2 | PET23-A | 94 | 0.4 | 1,108 | 4.1 | (Y)/(X)/(Y) | 0.59 | 0.05 |
| Example 3 | PET23-B | 94 | 0.4 | 1,108 | 4.1 | (Y)/(X)/(Y) | 0.57 | −0.30 |
| Example 4 | PET23-C | 94 | 0.4 | 1,108 | 4.1 | (Y)/(X)/(Y) | 0.19 | −0.68 |
| Example 5 | PET38 | 94 | 0.4 | 1,108 | 4.1 | (Y)/(X)/(Y) | −0.01 | −0.65 |
| Example 6 | PET75 | 93 | 0.4 | 1,108 | 4.1 | (Y)/(X)/(Y) | −0.68 | 0.29 |
| Example 7 | PET50 | 94 | 0.4 | 1,108 | 4.1 | (X)/(Y) | 0.50 | 0.05 |
| Example 8 | PET50 | 94 | 0.4 | 1,108 | 8.2 | (Y)/(X)/(Y) | 0.10 | 0.17 |
| Example 9 | PET50 | 94 | 0.4 | 1,108 | 2.4 | (Y)/(X)/(Y) | 0.61 | −0.51 |
| Comparative | PET50 | 94 | 0.4 | 1,108 | 1.5 | (Y)/(X)/(Y) | 0.90 | −0.89 |
| Example 1 | | | | | | | | |
| Comparative | PET50 | 94 | — | — | 10.0 | — | — | — |
| Example 2 | | | | | | | | |
| Comparative | PET23-D | 83 | 0.4 | 1,108 | 4.1 | (Y)/(X)/(Y) | 1.35 | −1.56 |
| Example 3 | | | | | | | | |
| Comparative | PET12 | 82 | 0.4 | 1,108 | 4.1 | (X)/(Y) | −1.43 | 1.44 |
| Example 4 | | | | | | | | |
| | Evaluation | | | | | | | |
| | water vapor | oxygen | | | | | | |
| | trans- | trans- | | | | | | |
| | mission | mission | | | | | | |
| | rate | rate | clarity | clarity | clarity | clarity | clarity | clarity |
| | *1 | *2 | 1 | 2 | 3 | 4 | 5 | 6 |
| Example 1 | 3.0 × 10⁻³ | <0.01 | A | A | A | A | A | A |
| Example 2 | 2.9 × 10⁻³ | <0.01 | A | A | A | A | A | A |
| Example 3 | 3.1 × 10⁻³ | <0.01 | A | A | A | A | A | A |
| Example 4 | 4.3 × 10⁻³ | <0.01 | A | A | A | A | A | A |
| Example 5 | 3.0 × 10⁻³ | <0.01 | A | A | A | A | A | A |
| Example 6 | 3.5 × 10⁻³ | <0.01 | A | A | A | A | A | A |
| Example 7 | 9.7 × 10⁻³ | 0.06 | A | A | A | A | A | A |
| Example 8 | 5.5 × 10⁻³ | <0.01 | A | A | A | A | A | A |
| Example 9 | 4.1 × 10⁻³ | 0.05 | B | B | B | B | B | B |
| Comparative | 4.5 × 10⁻³ | <0.01 | C | C | C | C | C | C |
| Example 1 | | | | | | | | |
| Comparative | — | — | — | — | — | — | — | — |
| Example 2 | | | | | | | | |
| Comparative | 3.0 × 10-3 | <0.01 | D | D | D | D | D | D |
| Example 3 | | | | | | | | |
| Comparative | 2.0 × 10-1 | 0.1 | D | D | D | D | D | D |
| Example 4 | | | | | | | | |

*1 g/(m² · day)
*2 cc/(m² · day · atm)

### Evaluation Method

### (5′) Clarity

In the case in which the number of panelists who rated the clarity as A is greater than that in the results of the evaluation in Example 1 made in accordance with Evaluation Method (5), the rating was “favorable”; in the case the number is equal, the rating was “comparable”; and in the case in which the number of panelists who rated the clarity as A decreased, the rating was “decreased.”

### (8) Viscosity

The viscosity of each of the coating liquids obtained in Examples was measured with a Brookfield rotational viscometer. The measurement conditions were as follows.
Device: analog viscometer LVT, produced by AMETEK Brookfield
Spindle: No. 63
Rotation number: 6 rpm

### (9) Surface Roughness

The surface roughness of the layer (Y) of each of the multilayer structures obtained in Examples and Comparative Examples was evaluated using a scanning white-light interferometric microscope. The measurement conditions were as follows. A difference between the highest point and the lowest point in a measurement range was defined as a surface roughness, and an average of values at ten sites was employed as the surface roughness.
Device: non-contact surface/layer cross sectional shape measuring system VertScan, produced by Hitachi High-Tech Science Corporation
Measurement range: 2.5 mm×2.5 mm

### Examples 10 to 13

Multilayer structures and electronic-device protective sheets were produced and evaluated in the same manner as in Example 1, except that the stirring time was adjusted such that the viscosity of the coating liquid (S) measured by the method disclosed in Evaluation Method (8) was as shown in Table 2. Furthermore, the surface roughness of the layer (Y) of each of the obtained multilayer structures was measured by the method disclosed in Evaluation Method (9). The results are shown in Table 2. It is to be noted that the clarity was evaluated by the method disclosed in Evaluation Method (5′).

TABLE 2

| | Layer (Y) | | | | | Evaluation | |
|---|---|---|---|---|---|---|---|
| | coating liquid (S) | | color | | surface | water vapor | oxygen |
| | | viscosity | a* | b* | roughness | transmission rate | transmission rate |
| | type | mPa · s | — | — | nm | *1 | *2 |
| Example 10 | S-1 | 3,000 | 0.15 | −0.24 | 42 | 3.0 × 10⁻³ | <0.01 |
| Example 11 | S-1 | 4,000 | 0.14 | −0.23 | 58 | 2.9 × 10⁻³ | <0.01 |
| Example 12 | S-1 | 2,000 | 0.14 | −0.25 | 41 | 3.0 × 10⁻³ | <0.01 |
| Example 13 | S-1 | 4,500 | 0.14 | 0.22 | 63 | 2.8 × 10⁻³ | <0.01 |

| | Evaluation | | | | | |
|---|---|---|---|---|---|---|
| | clarity | clarity | clarity | clarity | clarity | clarity |
| | 1 | 2 | 3 | 4 | 5 | 6 |
| Example 10 | favorable | favorable | favorable | favorable | favorable | favorable |
| Example 11 | favorable | favorable | favorable | favorable | favorable | favorable |
| Example 12 | favorable | favorable | favorable | favorable | favorable | favorable |
| Example 13 | comparable | comparable | comparable | comparable | comparable | comparable |

*1 g/(m² · day)
*2 cc/(m² · day · atm)

### Evaluation Method

### (10) Evaluation of Contact Angle

One face of the PET50 was subjected to a surface treatment at an intensity of 130 W min/m² by using a corona treatment device TEC-4AC, produced by Kasuga Denki, Inc. Next, the base was set on a stage of the device, a droplet of the coating liquid (S) was dropped onto the corona treatment face of the PET50 under the following conditions, and the water contact angle was measured under conditions involving 23° C. and 50% RH. This operation was repeated ten times, and the evaluation was performed employing an average value as the contact angle.
Device: Drop Master DM-500, produced by Kyowa Interface Science Co., Ltd.
Droplet: 2.0 μL
Waiting time: 2.0 sec

### (11) Standard Deviation of Luminance of Multilayer Structure

Each of the multilayer structures obtained in Examples was cut into a size of 21.0 cm in the TD×29.7 cm in the MD. Next, in a state in which white light was delivered from a white light source to one face of the multilayer structure at an angle of 250 with respect to the vertical direction of the multilayer structure and the reflected light could be measured with a line sensor camera on a face side on which the white light source was provided and at an angle of −30° with respect to the vertical direction of the multilayer structure, the measurement was performed while the film was moved at a constant speed in the MD. Luminance values within a range of a width (in the TD) of 12 mm at the center point in the MD of a measurement range were fit with a quadratic function by a least-squares method. The baseline correction was performed using the obtained data as a baseline to calculate differences between the values obtained by fitting by the least-squares method and the measured values. The minimum value of the standard deviation of the luminance after the baseline correction was employed as standard deviation of the luminance of the multilayer structure. The measurement conditions were as follows.
White Light Source (High-Luminance Line LED Lighting)
Light source: LED light source PFBR-150, produced by CCS Inc.
Set intensity: 100%
Width of line LED lighting: 60 cm
Distance to multilayer structure in vertical direction: 10 cm
Line Sensor Camera
Camera: line scan camera NSUF4010S-F(CI), produced by Nippon Electro-Sensory Devices Corporation
Lens: YF5028, produced by Ricoh Imaging Co. Ltd.
Distance to multilayer structure in vertical direction: 15 cm

### Examples 14 to 17

Coating liquids (S-2) to (S-6) were produced by the same procedure as the coating liquid (S-1) of Example 1, except that at the time of producing the coating liquid (S-1) in Example 1, the dropped amount of 18.80 parts by mass of methanol dropped last was appropriately adjusted such that the water/methanol ratio of the coating liquid (S) was changed as shown in Table 3. Multilayer structures and electronic-device protective sheets were produced and evaluated in the same manner as in Example 1, except that the coating liquids (S-2) to (S-6) were used instead of the coating liquid (S-1). Furthermore, with regard to the coating liquids (S-2) to (S-6), the contact angle was evaluated by the method disclosed in Evaluation Method (10). Moreover, with regard to the obtained multilayer structures, the standard deviation of luminance was measured by the method disclosed in Evaluation Method (11). The results are shown in Table 3. It is to be noted that the clarity was evaluated by the method disclosed in Evaluation Method (5′).

TABLE 3

| | Layer (Y) | | | | | | | |
|---|---|---|---|---|---|---|---|---|
| | | | | | | standard | Evaluation | |
| | coating | | | | | deviation of | water | |
| | liquid (S) | | | | | luminance of | vapor | oxygen |
| | | water/methanol | contact | color | | multilayer | transmission | transmission |
| | | ratio | angle | a* | b* | structure | rate | rate |
| | type | — | ° | — | — | — | *1 | *2 |
| Exam- | S-2 | 60/40 | 27 | 0.15 | −0.24 | 0.80 | 3.0 × 10⁻³ | <0.01 |
| ple 14 | | | | | | | | |
| Exam- | S-3 | 55/45 | 23 | 0.15 | −0.22 | 0.76 | 4.8 × 10⁻³ | <0.01 |
| ple 15 | | | | | | | | |
| Exam- | S-4 | 68/32 | 31 | 0.14 | −0.23 | 0.95 | 3.1 × 10⁻³ | <0.01 |
| ple 16 | | | | | | | | |
| Exam- | S-5 | 70/30 | 33 | 0.14 | −0.23 | 1.06 | 3.2 × 10⁻³ | <0.01 |
| ple 17 | | | | | | | | |

| | Evaluation | | | | | |
|---|---|---|---|---|---|---|
| | clarity | clarity | clarity | clarity | clarity | clarity |
| | 1 | 2 | 3 | 4 | 5 | 6 |
| Exam- | favorable | favorable | favorable | favorable | favorable | favorable |
| ple 14 | | | | | | |
| Exam- | favorable | favorable | favorable | favorable | favorable | favorable |
| ple 15 | | | | | | |
| Exam- | favorable | favorable | favorable | favorable | favorable | favorable |
| ple 16 | | | | | | |
| Exam- | comparable | comparable | comparable | comparable | comparable | comparable |
| ple 17 | | | | | | |

*1 g/(m² · day)
*2 cc/(m² · day · atm)

1. A multilayer structure comprising a base (X) and a layer (Y),
wherein
the layer (Y) comprises a reaction product (D) between an aluminum atom-containing metal oxide (A) and an inorganic phosphorus compound (BI),
the base (X) and the layer (Y) are adjacent to each other in at least one pair of the same, and
in a L*a*b* color system, an a* value is −0.8 or more and 0.8 or less and a b* value is −0.8 or more and 0.8 or less, the a* value and the b* value being measured in accordance with JIS Z 8722:2009.

2. The multilayer structure according to claim 1, wherein condition 1 is satisfied:
condition 1:
in a luminance analysis in which reflected light observed when the multilayer structure is moved at a constant speed in a machine direction (MD) in a state in which the multilayer structure is irradiated with light from a white light source is intermittently measured with a line sensor camera;
the light from the white light source is delivered to one face of the multilayer structure at an angle of 25° with respect to a vertical direction of the multilayer structure, and the reflected light is measured with the line sensor camera on a face side on which the white light source is provided and at an angle of −30° with respect to the vertical direction of the multilayer structure; and
a minimum value of standard deviation of luminance values calculated from values obtained in such a manner that baseline correction is performed on obtained luminance by fitting, by a least-squares method, luminance values within a range of a width (in a transverse direction (TD)) of 12 mm at a center point in the MD of a measurement range is 1.2 or less.

3. The multilayer structure according to claim 1, wherein a surface roughness of the layer (Y) measured by white-light interferometry is 70 nm or less.

4. The multilayer structure according to claim 1, wherein a water vapor transmission rate is 1×10⁻² g/m²·day or less as measured at 40° C. and 90% RH in accordance with ISO 15106-3:2003.

5. The multilayer structure according to claim 1, wherein the base (X) comprises a surface layer.

6. The multilayer structure according to claim 1, comprising at least one pair of the base (X) and the layer (Y) which are directly laminated.

7. The multilayer structure according to claim 1, comprising at least one pair of the base (X) and the layer (Y) which are laminated via an adhesive layer (I).

8. The multilayer structure according to claim 1, comprising layers (Y) respectively disposed on both faces of the base (X).

9. The multilayer structure according to claim 1, wherein in an infrared absorption spectrum of the layer (Y), a maximum absorption wavenumber in a region of 800 to 1,400 cm⁻¹ falls within a range of 1,080 to 1,130 cm⁻¹.

10. The multilayer structure according to claim 1, wherein an image clarity of the base (X) at an optical comb width of 0.25 mm, the image clarity being measured in accordance with ISO 17221, is 85% or more.

11. The multilayer structure according to claim 1, wherein a difference between the a* value and the b* value (a* value−b* value) is −1.0 or more and 1.0 or less.

12. A method for producing a multilayer structure, the method comprising:
a step (I) of forming a precursor layer of a layer (Y) by applying, onto at least one face of a base (X), a coating liquid (S) comprising an aluminum atom-containing metal oxide (A), an inorganic phosphorus compound (BI), and a solvent, followed by drying the coating liquid (S) by heating at a temperature of 120° C. or more to remove the solvent; and
a step (II) of forming the layer (Y) by subjecting the precursor layer of the layer (Y) to a heat treatment,
wherein
in the step (I), a time period from the completion of the coating with the coating liquid (S) to the start of the drying by heating is 1.8 sec or more and 9.0 sec or less, and
in a L*a*b* color system of the multilayer structure obtained, an a* value is −0.8 or more and 0.8 or less and a b* value is −0.8 or more and 0.8 or less, the a* value and the b* value being measured in accordance with JIS Z 8722:2009.

13. The method for producing a multilayer structure according to claim 12, wherein the coating liquid (S) satisfies condition 2:
condition 2:
two seconds after a droplet of 2.0 μL of the coating liquid (S) is dropped at 23° C. and 50% RH onto a treatment face of a polyethylene terephthalate film which has been subjected to a surface treatment at an intensity of 130 W-min/m² by using a corona treatment device, a contact angle of the droplet is 20° or more and 35° or less.

14. The method for producing a multilayer structure according to claim 13,
wherein
the coating liquid (S) comprises a water/methanol mixed solvent as the solvent, and
the mixed solvent has a water/methanol ratio of 3.5/6.5 or more and 7/3 or less.

15. The method for producing a multilayer structure according to claim 12,
wherein
the coating liquid (S) has a viscosity of 400 mPa-s or more and 5,000 mPa-s or less, and
a surface roughness of the layer (Y) measured by white-light interferometry is 70 nm or less.

16. A protective sheet for an electronic device, the protective sheet comprising the multilayer structure according to claim 1.

17. The protective sheet according to claim 16, which is to be used in protecting a surface of a photoelectric conversion device, an information display device, or a lighting device.

18. An electronic device comprising the protective sheet according to claim 16.
